(19) United States
(12) Patent Application Publication
(10) Pub. No.: US 2026/0062831 A1
(43) Pub. Date: Mar. 5, 2026

(54) Shaped Solid Silicon Carbide Vapor Source Material Structure for use in a Sublimation System for Growing Crystalline Silicon Carbide

(71) Applicant: Wolfspeed, Inc., Durham, NC (US)

(72) Inventors: Valeri Fedorovich Tsvetkov, Durham, NC (US); William Henry Brixius, Hillsborough, NC (US); Steven Herbert Griffiths, Morrisville, NC (US); Brian Bennett Haidet, Raleigh, NC (US); Elif Balkas, Cary, NC (US); Caleb Andrew Kent, Durham, NC (US); Yuri I. Khlebnikov, Raleigh, NC (US)

(21) Appl. No.: 18/963,103

(22) Filed: Nov. 27, 2024

Related U.S. Application Data
(60) Provisional application No. 63/689,294, filed on Aug. 30, 2024.

(51) Int. Cl. C30B 23/00; C30B 29/36

(52) U.S. Cl. CPC C30B 23/00; C30B 29/36

(57) ABSTRACT

A silicon carbide source material structure for use in a sublimation system for growing crystalline silicon carbide is provided. The silicon carbide source material structure includes a composite shaped solid. The composite shaped solid may be made by casting, extrusion, 3D printing, graphite conversion, or other suitable process.

### PRIORITY CLAIM

The present application claims the benefit of priority of U.S. Provisional Application Ser. No. 63/689,294, filed on Aug. 30, 2024, which is incorporated herein by reference.

### FIELD

The present disclosure relates generally to semiconductor workpieces and semiconductor workpiece fabrication.

### BACKGROUND

Power semiconductor devices are used to carry large currents and support high voltages. A wide variety of power semiconductor devices are known in the art including, for example, transistors, diodes, thyristors, power modules, discrete power semiconductor packages, and other devices. For instance, example semiconductor devices may be transistor devices such as Metal Oxide Semiconductor Field Effect Transistors (“MOSFET”), bipolar junction transistors (“BJTs”), Insulated Gate Bipolar Transistors (“IGBT”), Gate Turn-Off Transistors (“GTO”), junction field effect transistors (“JFET”), high electron mobility transistors (“HEMT”) and other devices. Example semiconductor devices may be diodes, such as Schottky diodes or other devices.

Power semiconductor devices may be packaged into various semiconductor device packages, such as discrete semiconductor device packages and power modules. Power modules may include one or more power devices and other circuit components and can be used, for instance, to dynamically switch large amounts of power through various components, such as motors, inverters, generators, and the like.

Semiconductor devices may be fabricated from wide bandgap semiconductor materials, such as silicon carbide and/or Group III nitride-based semiconductor materials. The fabrication process for power semiconductor devices may require processing of wide bandgap semiconductor wafers, such as silicon carbide semiconductor wafers.

Single crystal silicon carbide (SiC) has proven to be a very useful wafer material in the manufacture of such semiconductor devices. Due to its physical strength and excellent resistance to many chemicals, SiC may be used to fabricate very robust substrates adapted for use in the semiconductor industry. SiC has excellent electrical properties, including radiation hardness, high breakdown field, a relatively wide band gap, high saturated electron drift velocity, high-temperature operation, and absorption and emission of high-energy photons in the blue, violet, and ultraviolet regions of the optical spectrum.

SiC crystalline material may be produced using various seeded sublimation growth processes. In a typical SiC growth process, a seed material and source material are arranged in a reaction crucible which is then heated to the sublimation temperature of the source material. By controlled heating of the environment surrounding the reaction crucible, a thermal gradient is developed between the sublimating source material and the marginally cooler seed material. By means of the thermal gradient, source material in a vapor phase is transported onto the seed material where it condenses to grow a bulk crystalline boule. This type of crystalline growth process is commonly referred to as physical vapor transport (PVT) process.

A resulting SiC boule may then be sliced using into wafers, and the individual wafers may then be used as seed material for a seeded sublimation growth process, or as substrates upon which a variety of semiconductor devices (e.g., power semiconductor devices and optical applications, such as LEDs, windows, photo-diodes, etc.) may be formed.

### SUMMARY

Aspects and advantages of embodiments of the present disclosure will be set forth in part in the following description, or can be learned from the description, or can be learned through practice of the embodiments.

In an aspect, the present disclosure provides an example silicon carbide source material structure. In some implementations, the example silicon carbide source material structure includes a composite shaped solid.

In an aspect, the present disclosure provides a silicon carbide source material structure for use in a sublimation system for growing single crystal silicon carbide, the silicon carbide source material structure comprising: two or more shaped solids having a volume of 30 cm3 or greater.

In an aspect, the present disclosure provides a silicon carbide source material structure for use in a sublimation system for growing single crystal silicon carbide, the source material structure comprising: a shaped solid having a volume and a surface area, wherein the ratio of the surface area to the volume is about 2.0 cm⁻¹ or greater.

In an aspect, the present disclosure provides an example source material for use in a sublimation system for growing single crystal silicon carbide, the source material structure comprising: a shaped solid comprising at least one internal void having a volume of 1 mm³ or greater.

In an aspect, the present disclosure provides a silicon carbide source material structure for use in a sublimation system for growing single crystal silicon carbide, the source material structure comprising: a shaped solid structure having a surface and a hole extending from the surface into an interior of the solid structure, the hole having a depth of at least 1 mm from the surface.

In an aspect, the present disclosure is directed to a silicon carbide source material structure for use in a sublimation system for growing single crystal silicon carbide, the source material structure comprising: a shaped solid structure having a volume, wherein a ratio of the volume to the volume of the smallest right cylinder that would fully contain the shaped solid structure is about 0.9 or less.

In an aspect, the present disclosure is directed to a silicon carbide source material structure for use in a sublimation system for growing single crystal silicon carbide, the source material structure comprising: a composite shaped solid comprising a first portion configured to provide a first sublimation rate during a crystal growth process and a second portion configured to provide a second sublimation rate during a crystal growth process, wherein the second sublimation rate is different from the first sublimation rate.

Variations and modifications can be made to this example aspect of the present disclosure.

These and other features, aspects and advantages of various embodiments will become better understood with reference to the following description and appended claims. The accompanying drawings, which are incorporated in and constitute a part of this specification, illustrate embodiments of the present disclosure and, together with the description, serve to explain the related principles.

### BRIEF DESCRIPTION OF THE DRAWINGS

Detailed discussion of embodiments directed to one of ordinary skill in the art are set forth in the specification, which makes reference to the appended figures, in which:

FIG. 1 depicts a sublimation system according to example embodiments of the present disclosure;

FIG. 2 depicts a sublimation system according to example embodiments of the present disclosure;

FIG. 3 depicts a sublimation system according to example embodiments of the present disclosure;

FIG. 4A depicts at least a portion of a solid shaped silicon carbide source material structure according to example embodiments of the present disclosure;

FIG. 4B depicts at least a portion of a solid shaped silicon carbide source material structure according to example embodiments of the present disclosure;

FIG. 5A depicts a top view of at least a portion of a solid shaped silicon carbide source material structure according to example embodiments of the present disclosure;

FIG. 5B depicts a top view of at least a portion of a solid shaped silicon carbide source material structure according to example embodiments of the present disclosure;

FIG. 5C depicts a perspective view of at a source retention mechanism according to example embodiments of the present disclosure;

FIG. 5D depicts a perspective view of at a source retention mechanism according to example embodiments of the present disclosure;

FIG. 6A depicts a cross-sectional view of at least a portion of a solid shaped silicon carbide source material structure according to example embodiments of the present disclosure;

FIG. 6B depicts a cross-sectional view of at least a portion of a solid shaped silicon carbide source material structure according to example embodiments of the present disclosure;

FIG. 6C depicts a top view of the solid shaped silicon carbide source material structure shown in FIG. 6A;

FIG. 7A depicts a cross-sectional view of at least a portion of a solid shaped silicon carbide source material structure according to example embodiments of the present disclosure;

FIG. 7B depicts a cross-sectional view of at least a portion of a solid shaped silicon carbide source material structure according to example embodiments of the present disclosure;

FIG. 8 depicts a cross-sectional view of at least a portion of a solid shaped silicon carbide source material structure according to example embodiments of the present disclosure;

FIG. 9 depicts a cross-sectional view of at least a portion of a solid shaped silicon carbide source material structure according to example embodiments of the present disclosure;

FIG. 10 depicts at least a portion of a solid shaped silicon carbide source material structure according to example embodiments of the present disclosure;

FIG. 11 depicts at least a portion of a solid shaped silicon carbide source material structure according to example embodiments of the present disclosure;

FIG. 12 depicts at least a portion of a solid shaped silicon carbide source material structure according to example embodiments of the present disclosure;

FIG. 13A depicts a cross-sectional view of at least a portion of a solid shaped silicon carbide source material structure according to example embodiments of the present disclosure;

FIG. 13B depicts a cross-sectional view of at least a portion of a solid shaped silicon carbide source material structure according to example embodiments of the present disclosure;

FIG. 14 depicts a cross-sectional view at least a portion of a solid shaped silicon carbide source material structure according to example embodiments of the present disclosure;

FIG. 15A depicts a cross-sectional view at least a portion of a solid shaped silicon carbide source material structure according to example embodiments of the present disclosure;

FIG. 15B depicts a cross-sectional view at least a portion of a solid shaped silicon carbide source material structure according to example embodiments of the present disclosure;

FIG. 16 depicts at least a portion of a solid shaped silicon carbide source material structure according to example embodiments of the present disclosure;

FIG. 17 depicts at least a portion of a solid shaped silicon carbide source material structure according to example embodiments of the present disclosure;

FIG. 18 depicts at least a portion of a solid shaped silicon carbide source material structure according to example embodiments of the present disclosure;

FIG. 19 depicts at least a portion of a solid shaped silicon carbide source material structure according to example embodiments of the present disclosure;

FIG. 20 depicts at least a portion of a solid shaped silicon carbide source material structure according to example embodiments of the present disclosure;

FIG. 21 depicts at least a portion of a solid shaped silicon carbide source material structure according to example embodiments of the present disclosure;

FIG. 22A depicts a top view of a solid shaped silicon carbide source material structure according to example embodiments of the present disclosure;

FIG. 22B depicts a perspective view of a solid shaped silicon carbide source material structure according to example embodiments of the present disclosure;

FIG. 22C depicts a top view of a solid shaped silicon carbide source material structure according to example embodiments of the present disclosure;

FIG. 22D depicts a top view of a solid shaped silicon carbide source material structure according to example embodiments of the present disclosure;

FIG. 22E depicts a top view of a solid shaped silicon carbide source material structure according to example embodiments of the present disclosure;

FIG. 23 depicts a top view of a solid shaped silicon carbide source material structure according to example embodiments of the present disclosure;

FIG. 24 depicts a top view of a solid shaped silicon carbide source material structure according to example embodiments of the present disclosure;

FIG. 25 depicts a solid shaped silicon carbide source material structure according to example embodiments of the present disclosure;

FIG. 26 depicts a cross-sectional view at least a portion of a solid shaped silicon carbide source material structure according to example embodiments of the present disclosure;

FIG. 27 depicts a cross-sectional view at least a portion of a solid shaped silicon carbide source material structure according to example embodiments of the present disclosure;

FIG. 28 depicts a solid shaped silicon carbide source material structure according to example embodiments of the present disclosure;

FIG. 29 depicts a solid shaped silicon carbide source material structure according to example embodiments of the present disclosure;

FIG. 30 depicts a solid shaped silicon carbide source material structure according to example embodiments of the present disclosure;

FIG. 31 depicts a solid shaped silicon carbide source material structure according to example embodiments of the present disclosure;

FIG. 32 depicts a solid shaped silicon carbide source material structure according to example embodiments of the present disclosure;

FIG. 33A depicts a solid shaped silicon carbide source material structure according to example embodiments of the present disclosure;

FIG. 33B depicts a top view of the solid shaped silicon carbide source material structure of FIG. 33A;

FIG. 34 depicts a solid shaped silicon carbide source material structure according to example embodiments of the present disclosure;

FIG. 35 depicts a solid shaped silicon carbide source material structure according to example embodiments of the present disclosure;

FIG. 36 depicts a powder bed fusion system that may be used according to example embodiments of the present disclosure;

FIG. 37 depicts a fused deposition modeling system according to example embodiments of the present disclosure;

FIG. 38 depicts a three-dimensional structure that may be formed from the composition according to example embodiments of the present disclosure; and

FIGS. 39A-39C are cross-sectional views of FIG. 38 taken along a line 3A-3A, depicting a process for forming a three-dimensional structure according to example embodiments of the present disclosure.

FIG. 40 depicts a flow chart diagram of an example method according to example embodiments of the present disclosure.

FIGS. 41A-48 depict example crystal growth systems that include a baffle according to example embodiments of the present disclosure.

### DETAILED DESCRIPTION

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations can be made to the embodiments without departing from the scope or spirit of the present disclosure. For instance, features illustrated or described as part of one embodiment can be used with another embodiment to yield a still further embodiment. Thus, it is intended that aspects of the present disclosure cover such modifications and variations.

Example aspects of the present disclosure are directed to systems for growing crystalline silicon carbide (SiC), such as single crystal SiC. In some SiC growth processes, the reaction crucible is made of carbon (including, for example graphite and/or other carbon materials) and is heated using an inductive or resistive heating technique. The heating coils and associated insulation are carefully positioned in relation to the reaction crucible to establish and maintain the desired thermal gradient. Source material, such as powdered SiC, is commonly used in conjunction with vertically oriented or horizontally oriented reaction crucibles. The powdered SiC is retained in a lower portion of the reaction crucible and the seed material is positioned in an upper portion of the reaction crucible during the PVT process.

Example embodiments of the present disclosure include a shaped solid silicon carbide source material structure. In some embodiments, the structure may have a composite shape.

As used herein, “composite shape” and “composite shaped” refer to any three-dimensional object or component that deviates from a regular cylindrical shape, or a composite solid structure containing multiple shaped solids which may have simple or complex shapes.

Deviations from a cylindrical shape include forms with regular or irregular geometries that do not conform to the typical circular or elliptical cross-section of a cylinder. Such structures may exhibit various shapes, including but not limited to structures with polygonal cross-sections; irregularly curved structures; and shapes with holes, voids, surface variations, or combinations thereof. The term also includes shapes containing multiple interconnected or distinct substructures. The substructures may themselves be composite shaped or may be cylindrically shaped. The term encompasses a wide range of geometric configurations and excludes objects that maintain a uniform cylindrical profile throughout their entire volume.

As used herein, “shaped solid” and “solid structure” refer to non-powdered solid components. A non-powdered component, for example, can have a size in at least one dimension of about 1 μm or greater, such as about 10 μm or greater, such as about 50 μm or greater, such as about 100 μm or greater, such as about 200 μm or greater, such as about 1000 μm or greater, such as about 1700 μm or greater, such as about 5 mm or greater, such as about 10 mm or greater. In some example embodiments, a shaped solid or solid structure may be formed by binding powdered particles together to form a composite material. Shaped solids may be shaped in an intentional manner to influence relevant properties, such as sublimation rate, vapor flow paths, thermal gradients, etc. Shaped solids may have one or more shape modifications. Shape modifications are intentional modifications to a source structure to influence relevant properties, such as sublimation rate, vapor flow paths, thermal gradients, etc.

The use of a composite shaped solid silicon carbide source material structure can provide the sublimation system with various advantages to enhance crystal growth. For example, the shaped solid source material may have a greater density than a powdered source material, which allows the source material to take up less space in the reactor, leaving more space to grow the silicon carbide boule. As such, the system can produce single crystal silicon carbide boules having greater heights than are possible with similar systems using a powdered source material. Additionally, the shaped solid source material may provide the system with higher crystal growth rates. For example, the density, porosity, and surface area of the source material may be controlled to provide faster sublimation of the silicon carbide, resulting in higher growth rates. Further, the shaped solid source material may be designed to provide better control of thermal gradients, surface area, and flow paths within the source material. For example, a composite shaped structure may include complex geometry including shapes, features, symmetry, asymmetry, dimensions, thicknesses, and/or appendages to improve such parameters. As such, significant performance improvements can be achieved compared to using, for instance, powder bed source material.

In some embodiments, the shaped solid source material may have features that provide desired thermal gradients within the source material. In some embodiments, the shaped solid source material may have features that provide high surface area for better sublimation rates. In some embodiments, the shaped solid source material may have features that provide desired gas flow paths through the source material to efficiently transport the sublimated SiC. In some embodiments, the shaped solid source material may have features that are tailored based on known local variations (e.g., temperature variations) within the crucible. In some embodiments, the shaped solid source material may have features that allow for directional control of the gas flow or heat flow within the source. In some embodiments, the shaped solid source material may have features that allow for control of the sublimation rate over time. Such features are described in more detail below with reference to the drawings.

The source material can be intentionally shaped to control the sublimation rate over time and thus during various stages of crystal growth. For example, if desired, during the beginning of the crystal growth process, the source material can be shaped such that a low surface area is exposed to obtain a relatively low sublimation rate. During a middle stage of crystal growth, if a higher sublimation rate is desired, the source can be shaped such that the exposed surface area increases relative to the beginning stage. For instance, after an upper or outer portion of the shaped source material is removed via sublimation, the layer that emerges as the new upper or outer layer can have more exposed surface area and thus a higher sublimation rate. It should be understood that any number of such stages may be designed. For example, during a third stage of crystal growth, it may be desired to decrease the sublimation rate again or to further raise the sublimation rate. The source can be designed accordingly by shaping it such that the next portion to emerge as the upper or outer layer has either a higher or lower surface area than the middle stage.

The source material can also be shaped to obtain a desired vapor flow/local vapor pressure relative to the seed/growing crystal surface. For example, the source material can be shaped to have areas of increased sublimation rates in one portion of the crucible relative to others. In some embodiments, for instance, it may be desired to have increased sublimation in the center of the seed/growing crystal and less sublimation on its periphery. Therefore, the source can be designed to have increased surface area in central portions relative to peripheral portions. Such vapor flow/pressure characteristics can change depending on temperature regions and stage of the growth process, thereby controlling the shape of the growing crystal. Such features are described in more detail below with reference to the drawings.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

It will be understood that when an element such as a layer, structure, region, or substrate is referred to as being “on” or extending “onto” another element, it may be directly on or extend directly onto the other element or intervening elements may also be present and may be only partially on the other element. In contrast, when an element is referred to as being “directly on” or extending “directly onto” another element, there are no intervening elements present, and may be partially directly on the other element. It will also be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present.

As used herein, a first structure “at least partially overlaps” or is “overlapping” a second structure if an axis that is perpendicular to a major surface of the first structure passes through both the first structure and the second structure. A “peripheral portion” of a structure includes regions of a structure that are closer to a perimeter of a surface of the structure relative to a geometric center of the surface of the structure. A “center portion” of the structure includes regions of the structure that are closer to a geometric center of the surface of the structure relative to a perimeter of the surface. “Generally perpendicular” means within 15 degrees of perpendicular. “Generally parallel” means within 15 degrees of parallel.

Relative terms such as “below” or “above” or “upper” or “lower” or “horizontal” or “lateral” or “vertical” may be used herein to describe a relationship of one element, layer or region to another element, layer or region as illustrated in the figures. It will be understood that these terms are intended to encompass different orientations of the device in addition to the orientation depicted in the figures.

Embodiments of the disclosure are described herein with reference to cross-section illustrations that are schematic illustrations of idealized embodiments (and intermediate structures) of the invention. The thickness of layers and regions in the drawings may be exaggerated for clarity. Additionally, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. Similarly, it will be understood that variations in the dimensions are to be expected based on standard deviations in manufacturing procedures. As used herein, “approximately” or “about” includes values within 10% of the nominal value.

Like numbers refer to like elements throughout. Thus, the same or similar numbers may be described with reference to other drawings even if they are neither mentioned nor described in the corresponding drawing. Also, elements that are not denoted by reference numbers may be described with reference to other drawings.

Some embodiments of the invention are described with reference to semiconductor layers and/or regions which are characterized as having a conductivity type such as n type or p type, which refers to the majority carrier concentration in the layer and/or region. Thus, n type material has a majority equilibrium concentration of negatively charged electrons, while p type material has a majority equilibrium concentration of positively charged holes. Some material may be designated with a “+” or “−” (as in n+, n−, p+, p−, n++, n−−, p++, p−−, or the like), to indicate a relatively larger (“+”) or smaller (“−”) concentration of majority carriers compared to another layer or region. However, such notation does not imply the existence of a particular concentration of majority or minority carriers in a layer or region.

In the drawings and specification, typical embodiments are described and, although specific terms are employed, they are used in a generic and descriptive sense only and not for purposes of limitation of the scope set forth in the following claims.

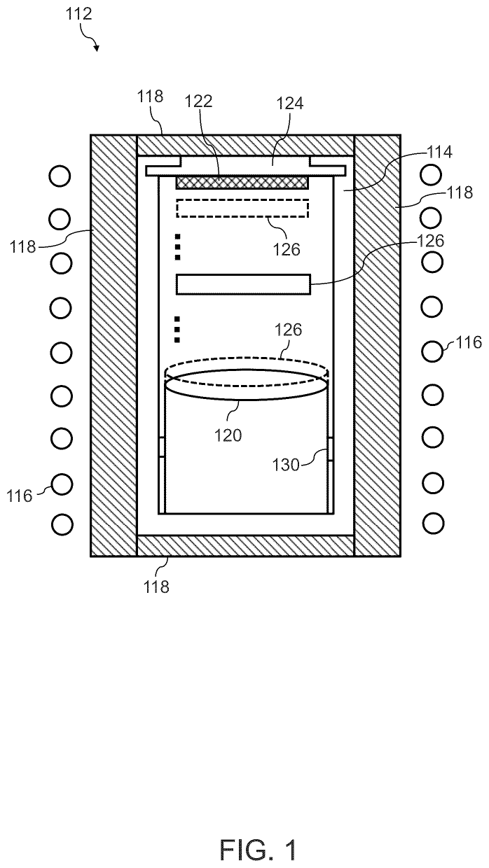

FIG. 1 is a cross sectional schematic diagram of a sublimation system 112 adapted for use in a seeded sublimation growth process of the type contemplated by certain embodiments of the disclosure. Sublimation system 112 includes a reaction crucible (also referred to as a susceptor or growth cell) 114 and a plurality of induction coils 116 adapted to heat reaction crucible 114 when electrical current is applied. Alternatively, a resistive heating approach may be applied to the heating of reaction crucible 114. Using any competent heating mechanism and approach, the temperature within a furnace housing sublimation system 112 may be controllable. The reaction crucible 114 may be made of graphite.

The furnace housing sublimation system 112 may also include one or more gas inlet and gas outlet ports and associated equipment allowing the controlled introduction and evacuation of gas from an environment surrounding reaction crucible 114. The introduction and evacuation of various gases to/from the environment surrounding reaction crucible 114 may be accomplished using a variety of inlets/outlets, pipes, valves, pumps, gas sources, and controllers. It will be further understood by those skilled in the art that sublimation system 102 may further incorporate in certain embodiments a water-cooled quartz vessel.

Reaction crucible 114 may be surrounded by insulation material 118. The composition, size, and placement of insulation material 118 will vary with individual sublimation systems 112 in order to define and/or maintain desired thermal gradients (both axially and radially) in relation to reaction crucible 114. For purposes of clarity, the term, “thermal gradient,” will be used herein to describe one or more thermal gradient(s) associated with reaction crucible 114. Those skilled in the art recognize that “the thermal gradient” established in embodiments of the disclosure will contain (or may be further characterized as having) axial and radial gradients, or may be characterized by a plurality of isotherms.

Prior to establishment of the thermal gradient, reaction crucible 114 is loaded with one or more source materials. As such, the reaction crucible includes one or more portions, as least one of which is capable of holding source material 120, which is represented by a generic cylinder for simplicity but, as further described herein, includes a shaped solid silicon carbide structure. As illustrated in FIG. 1, source material 120 may be held in a lower portion of reaction crucible 114, as is common for one type of reaction crucible 114.

A seed material 122 may be placed above or in an upper portion of reaction crucible 114. Seed material 122 may take the form of a mono-crystalline SiC seed wafer having a diameter from about 50 to about 300 mm. A SiC single crystal boule will be grown from seed material 122 during the seeded sublimation growth process. The seed material 122 may have a 4H crystal structure, 6H crystal structure, or other crystal structure. The seed material 122 can be on-axis (e.g., end face parallel to the (0001) plane) or off-axis (e.g., end face non-parallel to the (0001) plane). Growth may occur on the silicon face or the carbon face of the seed material 122.

In some embodiments, the system may include a baffle 126. The baffle 126 may provide a mechanism for the transport of source vapor during sublimation of the source material 120. The baffle 126 may have any spatial orientation relative to the source material 120, the seed crystal 122, and/or the reaction crucible 114. The baffle 126 may filter or otherwise reduce impurities from the source material in a crystal growth process. The baffle 126 may provide for control of radiative heat transfer. The baffle 126 may include any of the baffles disclosed in U.S. patent application Ser. No. 18/962,454 filed on Nov. 27, 2024, which is incorporated herein by reference.

As shown in FIG. 1, the baffle 126 or baffle elements may be located on the source material, may be spaced apart from the source material 120 and/or the seed material 122, or may be proximate the seed material 122. In some embodiments, the system 112 may include any number of baffles or baffle elements 126 without deviating from the scope of the present disclosure. In some embodiments, the source material 120 may have a baffle 126 or baffle element incorporated therein.

In the embodiment illustrated in FIG. 1, a seed holder 124 is used to hold seed material 122. Seed holder 124 is securely attached to reaction crucible 114 in an appropriate fashion using conventional techniques. For example, in the orientation illustrated in FIG. 1, seed holder 124 is attached to an uppermost portion of reaction crucible 114 to hold seed material 122 in a desired position. In one embodiment, seed holder 124 is fabricated from carbon. The attachment of the seed material (i.e., a seed wafer) to a corresponding seed holder within a sublimation system may be made with, for instance, a uniform thermal contact. Various techniques may be used to implement a uniform thermal contact. For example, the seed material may be placed in direct physical contact with the seed holder, or an adhesive may be used to fix the seed material to the seed holder, so as to ensure that conductive and/or radiative heat transfer is uniform over substantially the entire area between the seed and the seed holder. Alternately, a wafer holder comprising a controlled gap structure may be used to define and maintain a desired separation gap between the seed material and the seed holder. It will also be understood by those skilled in the art that the use of a controlled gap structure requires a protective backside surface coating on the seed material (i.e., on the surface opposite to the growth surface) so that the seed material will not inadvertently sublimate during the growth process. In various embodiments, a controlled gap structure may be used to form a separation distance between the seed material and seed holder of 10 μm or less, 5 μm or less, 2 μm or less, and where practically possible less than 1 μm. The thickness of the seed material 122 may be from about 0.1 mm to about 5 mm, such as from about 0.2 mm to about 2 mm, such as from about 0.3 mm to about 1 mm, such as from about 0.4 mm to about 0.7 mm.

In some embodiments, the sublimation system may include a second source material. The second source material can be a solid shaped source material according to any of the embodiments described herein or may be another type of silicon carbide vapor source material. The second source material may be located anywhere within the crucible. For example, it may be spaced axially, radially, or concentrically from a first solid source structure.

Further, the sublimation system 112 may optionally include a source material holder 130. The source material holder 130 may be, for example, one or more graphite components within the crucible that brace or support the shaped solid source material. In some embodiments, the source material holder 130 may be attached to the inner walls of the reaction crucible 114, as shown in FIG. 1.

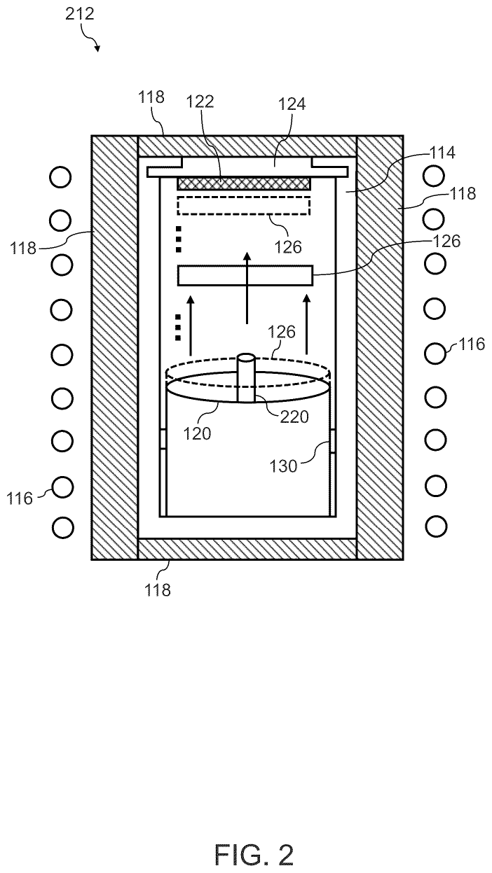

In one example embodiment, shown in FIG. 2, sublimation system 212 may be similar to that shown in FIG. 1, but also includes an inlet 220 for introducing a dopant (e.g., N₂) to the reaction crucible 114. The inlet 220, may be, for example, a tube, pipe, vent, or the like. In some embodiments, the source material 120 may surround the inlet 220. For example, in some embodiments, the solid shaped source material structure may include a channel through which the inlet 220 is provided. In other embodiments, the solid shaped source material structure may include a plurality of subcomponents (attached or detached) which surround the inlet 220. The inlet 220 may be connected to a dopant-containing gas source (not shown) and configured to introduce the dopant-containing gas to the reaction crucible 114. An example of a dopant-containing gas is nitrogen. In some embodiments, the system may include a baffle 126. The baffle 126 may provide a mechanism for the transport of source vapor during sublimation of the source material 120. The baffle 126 may have any spatial orientation relative to the source material 120, the seed crystal 122, and/or the reaction crucible 114. The baffle 126 may filter or otherwise reduce impurities from the source material in a crystal growth process. The baffle 126 may provide for control of radiative heat transfer. The baffle 126 may include any of the baffles disclosed in U.S. patent application Ser. No. 18/962,454 filed on Nov. 27, 2024, which is incorporated herein by reference.

As shown in FIG. 2, the baffle 126 may be located on the source material, may be spaced apart from the source material 120 and/or the seed material 126, or may be proximate the seed material 122. In some embodiments, the system 212 may include any number of baffles 126 without deviating from the scope of the present disclosure.

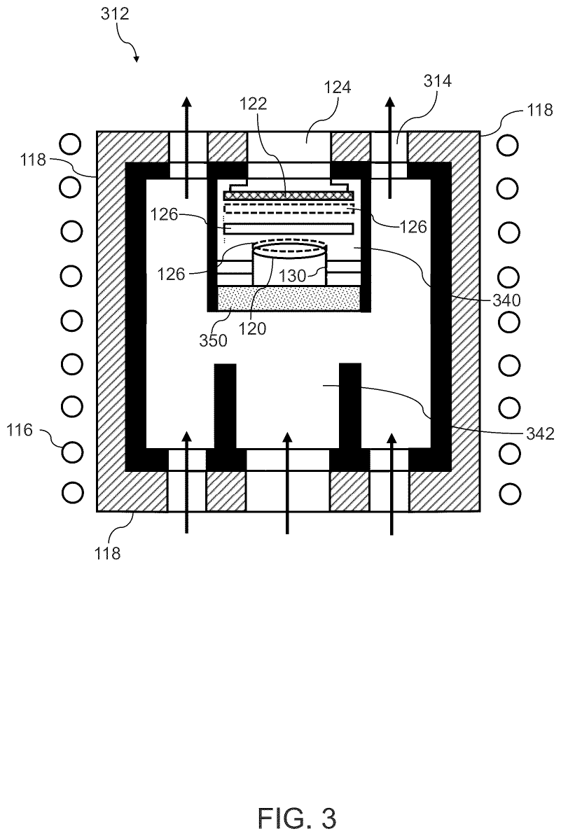

In another example embodiment, shown in FIG. 3, sublimation system 312 may be a continuous feed PVT (CF-PVT) system. In the CF-PVT system, the reaction crucible 314 may include an upper chamber 340 and a lower chamber 342. The upper chamber 340 may include the solid source material 120 and the seed material 122. The upper chamber 340 may be separated from the lower chamber 342 by a foamed structure 350. The foamed structure 350 may be formed, for example, from a gas-permeable graphite foam. The solid source material 120 may be placed on the foamed structure 350 within the upper chamber. A gaseous silicon source (e.g., trimethylsilane diluted in argon) may be supplied to the lower chamber. As the gaseous silicon source flows through the foamed structure 350, it may react with a carbon source within the foamed structure 350 (e.g., graphite) to form silicon carbide. The CF-PVT system combines the PVT process for the growth of single crystals and HTCVD process for the in-situ formation and continuous feeding of high purity polycrystalline source. The CF-PVT system may be particularly useful for growing 3C silicon carbide.

In some embodiments, the system may include a baffle 126. The baffle 126 may provide a mechanism for the transport of source vapor during sublimation of the source material 120. The baffle 126 may have any spatial orientation relative to the source material 120, the seed crystal 122, and/or the reaction crucible 114. The baffle 126 may filter or otherwise reduce impurities from the source material in a crystal growth process. The baffle 126 may provide for control of radiative heat transfer. The baffle 126 may include any of the baffles disclosed in U.S. patent application Ser. No. 18/962,454 filed on Nov. 27, 2024, which is incorporated herein by reference.

As shown in FIG. 3, the baffle 126 may be located on the source material, may be spaced apart from the source material 120 and/or the seed material 126, or may be proximate the seed material 122. In some embodiments, the system 312 may include any number of baffles 126 without deviating from the scope of the present disclosure. In some examples, the crystal growth processes (e.g., the processes conducting in any of the embodiments shown in FIGS. 1-3) may be conducted at process temperatures in a range of 1700° C. to about 2600° C.

In any of the embodiments shown in FIGS. 1-3 or any other suitable sublimation growth systems, reaction crucible 114 may be implemented in a number of different shapes and may hold one or more source materials accordingly. Thus, while embodiments of the present disclosure may be illustrated with certain reaction crucible designs, the scope of the present disclosure is not limited to such designs but will find application in different sublimation systems using many different types of reaction crucibles.

For any of the crystal growth systems provided herein, one or more parts of the crystal growth system or the source material may be 3D printed, such as disclosed in U.S. Provisional Application Ser. No. 63/689,298, which is incorporated herein by reference.

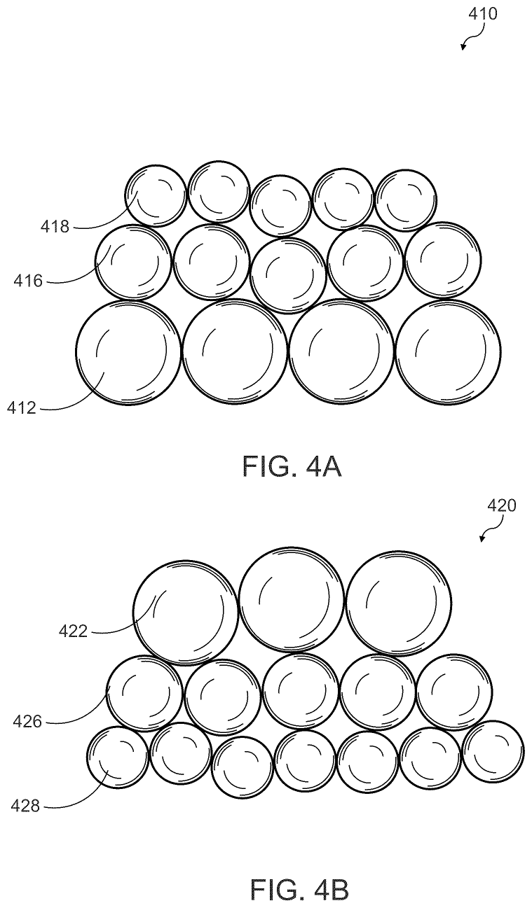

In any of the embodiments shown in FIGS. 1-3 or any other suitable sublimation growth systems, the source material 120 is a shaped solid structure containing silicon carbide. This invention is intended to cover sources that are shaped to achieve certain characteristics to improve SiC crystal growth by shaping the source in any shape based on desired properties (e.g., sublimation rate, sublimation direction, vapor flow, etc.) while considering temperature gradients/regions in the growth chamber, desired crystal characteristics etc., and/or changing or maintaining these growth or crystal characteristics based on the stage of the crystal growing process (e.g., initial growth on the seed, intermediate phase, and end of crystal growth). More complex figures are shown to exemplify that the solid sources can have simple or very complicated shapes. Any of the shapes shown in these figures can show shape features that can be used in the shape shown or together with shapes or shape features of other figures, such as surfaces with multiple inflection points, angles, curves, structures with interconnected channels and voids, stand alone voids and channels, variable exposed surface areas, constant exposed surface area during growth etc. Furthermore, these shaped sources are shown as single figures, but the shaped sources can comprise a single or multiple of these shaped sources (whether the same shape or different shapes) as well as shapes using features from different figures to form a shape or multiple shapes that are not expressly shown in the figures. Various example embodiments of the source material structure are illustrated in FIGS. 4-35, as described below.

According to examples of the present disclosure, the silicon carbide source material structure comprises a composite shaped solid. In some embodiments, the shaped solid comprises a composite solid structure. For example, the composite solid structure may include a prismatic shape having a cross section with a polygonal cross section. Examples may include triangular, square, rectangular, pentagonal, or hexagonal prisms, and the like. In another example embodiment, the composite solid structure may have an irregularly shaped cross-section.

In another example embodiment, the composite solid structure may include a core structure having at least one modification. The core structure, for example, may be any of the previously described prismatic or irregularly shaped solids. The core structure may also be cylindrical if it includes a modification.

In one embodiment, the modification may be a hole. As used herein, a hole means a cavity which extends from an outer surface of the structure. The surface from which the hole extends may be a flat or curved surface. The hole may have a regular or irregular shaped perimeter and/or cross-section. For example, the hole may have a curved or rectangular perimeter and/or cross section. The cross-section of the hole may be constant or variable as it extends into the perimeter of the core structure. In some embodiments, the hole may have a depth of at least 0.1 mm, such as at least 0.5 mm, such as at least 1 mm, such as at least 3 mm, such as at least 5 mm. In some embodiments, the hole may have a depth of at least about 25%, such as at least about 30%, such as at least about 40%, such as at least about 50%, such as at least about 60%, such as at least about 70%, such as at least about 80%, such as at least about 90% of the thickness of the shaped solid. The thickness of the shaped solid may be the distance from the perimeter of the hole to the opposite surface in a direction normal to the surface at the perimeter. As used herein, the depth of a hole is the distance from a perimeter of the hole to the maximum depth of the hole in a direction normal to the surface at the perimeter. In some embodiments, the hole is a channel. As used herein, a channel is a hole extending from one surface of the shaped solid to a second surface of the shaped solid or from one part of a surface to a second part of the same surface. In other embodiments, the hole only extends partially through the shaped solid structure such that it does not reach a second surface. In some embodiments, the shaped solid contains multiple holes, such as 2 or more holes, such as 3 or more holes, such as 5 or more holes, such as 10 or more holes, such as 20 or more holes. In one embodiment, the shaped solid may include a cylindrical core structure with a channel running from the top to bottom surface, forming a tubular structure.

In another embodiment, the modification may be a void. As used herein, a void means a cavity within the interior of the structure. A void is different from a hole as the cavity does not extend from the outer surface (other than as the result of any open porosity within the surrounding solid material). The void may have any shape, regular (e.g., spherical) or irregular. The void may be formed using a 3D printing process, as described below. Alternatively, the void may be formed by connecting multiple shaped solid substructures such that a void is left in the interior of the composite solid structure. Voids may also be formed by placing an organic material (e.g., a ball of polymeric material) within a powder matrix and sintering or otherwise solidifying the powder matrix. By this process, a void may be left in the space occupied by the organic material (e.g., after it incinerates or otherwise degrades leaving an open space). However, it should be understood that a void is different from a closed pore, which may be the result of microparticles bound together, leaving pores in the gaps. In this regard, a void is a shaped or non-random, intentionally formed feature, and may have a volume of about 0.065 mm³ or more, such as about 0.1 mm³ or more, such as about 0.5 mm³ or more, such as about 1 mm³ or more, such as about 10 mm³ or more, such as about 100 mm³ or more, such as about 1000 mm³ or more, such as about 4000 mm³ or more. In some embodiments, the shaped solid contains multiple voids, such as 2 or more voids, such as 3 or more voids, such as 5 or more voids, such as 10 or more voids, such as 20 or more voids. In some embodiments, the shaped solid may have at least one void having a volume of 1 mm³ or more, such as about 10 mm³ or more, such as about 100 mm³ or more, such as about 1000 mm³ or more, such as about 4000 mm³ or more.

In some embodiments, the modification may include a surface variation. A surface variation may include any modification deviating from the surrounding curvature or plane of the surface. However, a surface variation is different from surface roughness or open porosity that is an intrinsic property of the material. For example, the surface variation may be machined, cast, molded, 3D printed, etc.

In some embodiments, the surface variation may be an inflection point (i.e., a change in curvature). In some embodiments, the surface variation may be a hole. In some embodiments, the surface variation may be a slot. The slot may be an elongated cavity extending into an interior of a structure. In some embodiments, the surface variation may be a projection. The projection may be a ridge (an elongated raised portion extending outward from a surface of the structure), a pedestal (a projection having a flat surface generally parallel to the surface the projection extends from), a peak (a feature extending from a surface and having a single point of maximum projection from the surface), a mound (a projection having a rounded surface), or the like.

In some embodiments, the composite shaped solid may include an interconnection of substructures. As used herein, a substructure is an identifiable constituent shaped solid unit of a larger source material structure. A substructure may or may not be formed separately from other substructures or other portions of the rest of the source material structure. In one embodiment, the interconnected substructures may be joined at one or more joints. As used herein, joints are formed at the intersection of different substructures. A joint may be formed by adhering one substructure to another or it may be the portion where two substructures which are both part of a monolithic structure meet.

Examples of substructures include rods (parts having a generally but not necessarily perfectly cylindrical shape), facets (surfaces), rectangular prisms, triangular prisms, spheres, composite shaped structures, and the like. In some embodiments, the source material contains a facet having a flat surface. For example, in some embodiments, the source material may contain two facets which meet at a seam. The angle between the two facets at the seam may be from about 10 to about 80 degrees or from 100 to 170 degrees. In another embodiment, the source material contains a facet having a curved surface.

In some embodiments, the composite source material may include multiple separate shaped solids that can be placed in the reaction crucible together. The separate shaped solids may be arranged such that they are in contact with one another or not. For example, the composite source material may include an arrangement of solid silicon carbide spheres or rods.

One example embodiment of a composite shaped source material is shown in FIG. 4A. The composite source material 410 contains multiple spheres, including large spheres 412, medium spheres 416, and small spheres 418. The various spheres may be physically connected to each other or they may be separately placed in the desired arrangement within the crucible. As shown, the spheres progress from larger at the bottom and smaller at the top. Such a configuration may be used when there is a temperature gradient within the crucible. For example, if it is known that the bottom part of the crucible is hotter than the middle or top portion, and it is desired to maintain a uniform sublimation rate throughout the source material, the source material may be designed to have a smaller surface area per volume of the source material toward the bottom of the crucible and a higher surface area per volume of the source material toward the top of the crucible. As sublimation rate is a function of both temperature and surface area, the sublimation rate at a higher temperature and lower surface area may be similar to the sublimation rate at a lower temperature and higher surface area. In this way, a fist portion of the composite source material 410 may provide a first sublimation rate and a second portion of the composite source material 410 may provide a second sublimation rate that is different from the first sublimation rate.

In other embodiments, it may be desired to have the smaller relative surface area solids (e.g., bigger spheres) on top and the larger relative surface area solids (e.g., smaller spheres) on the bottom. For example, FIG. 4B shows a composite source material 420 containing multiple spheres, including large spheres 422 in an upper portion, medium spheres 426 in a middle portion, and small spheres 428 in a lower portion.

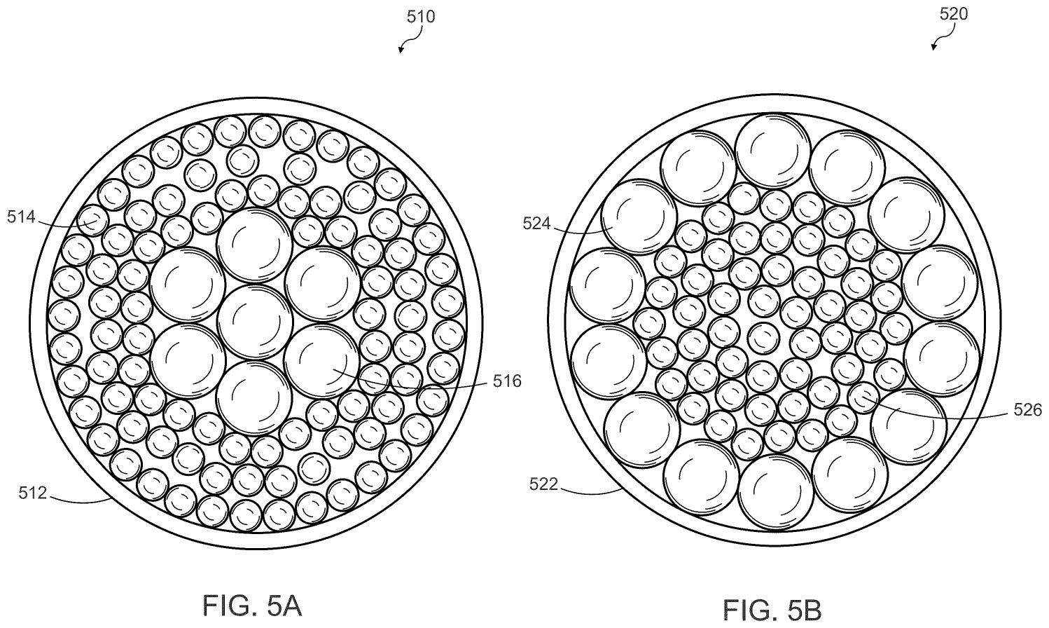

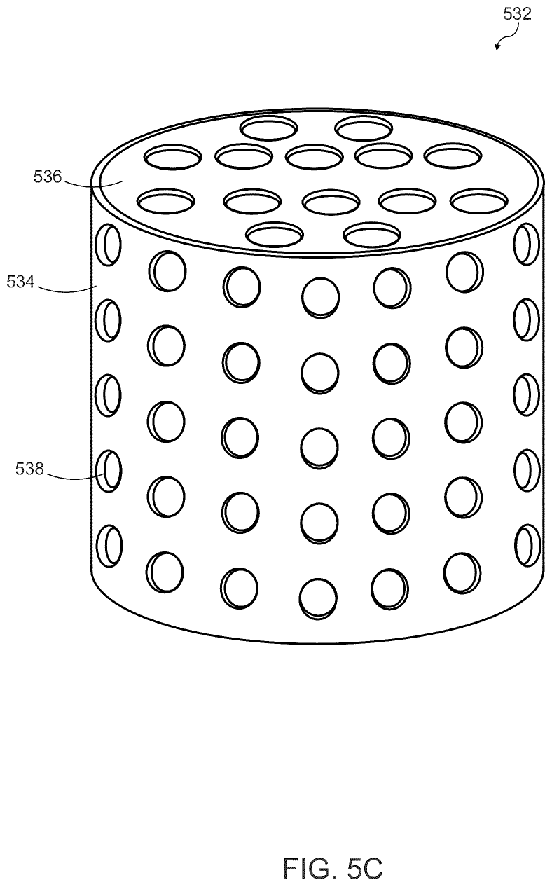

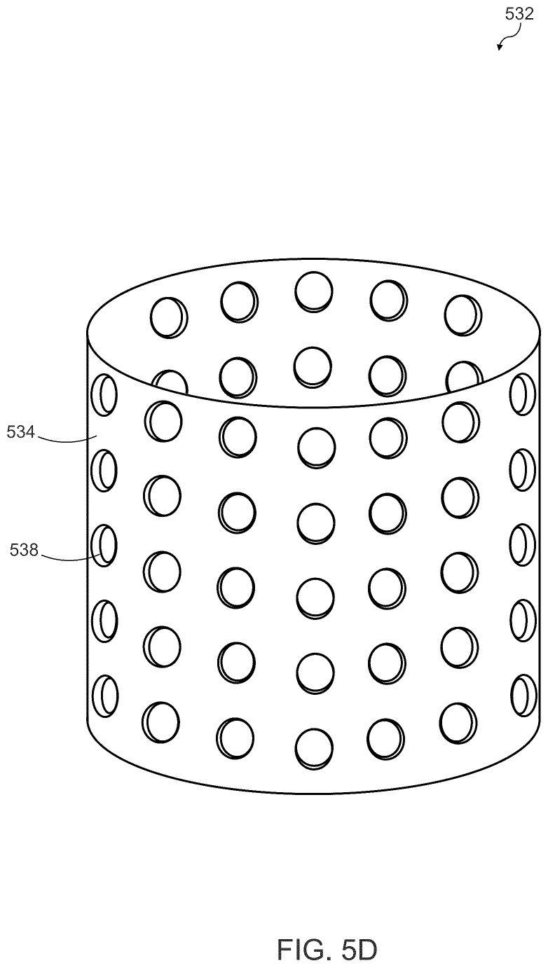

A top view of another example embodiment of a composite shaped source material is shown in FIG. 5A. The source material 510 includes many small spheres 514 surrounding larger spheres 516. The spheres 514 and 516 are contained by a source retention mechanism 512. The source retention mechanism 512 is in the form of a tube. The tube can be made from graphite or can be made from silicon carbide and thus function as part of the source material as well. The tube may also have channels, holes, voids, etc. through the wall of the tube to assist with vapor flow and heat flow. The various spheres may be physically connected (e.g., bonded) to each other or they may be separately placed in the desired arrangement within the source retention mechanism. In some embodiments, they may be in contact with the sides of the source retention mechanism. In some embodiments, they may be stable without contacting the source retention mechanism. In some embodiments, the source retention mechanism can be omitted. For example, if the various solids (e.g., spheres) are attached/connected to each other, are stable by themselves, or if the sides of the reaction crucible are used to contain the various solids, it can be omitted. However, the retention mechanism may still be desired to direct vapor flow in a designed manner. The same applies to any solid source structure described herein.

By placing the smaller spheres having a higher surface area per volume on the outside and the larger spheres having a smaller surface area per volume on in the center, the sublimation rate may be higher at the periphery of the crucible and thus more SiC vapor may flow to the edges of the seed/growing crystal.

Example embodiments of source retention mechanisms are shown in FIGS. 5C and 5D. in FIG. 5C, the source retention mechanism 532 contains cylindrical side walls 534, a cap 536, and channels 538 formed in the side walls 534 and the cap 536. As shown in FIG. 5C, the channels may all have the same or a similar diameter. In some embodiments, the diameters of the channels may be different and designed based on desired vapor flow paths and flowrates. For example, in some embodiments, the cap may have larger channels, or even one large central channel, relative to smaller or no peripheral channels.

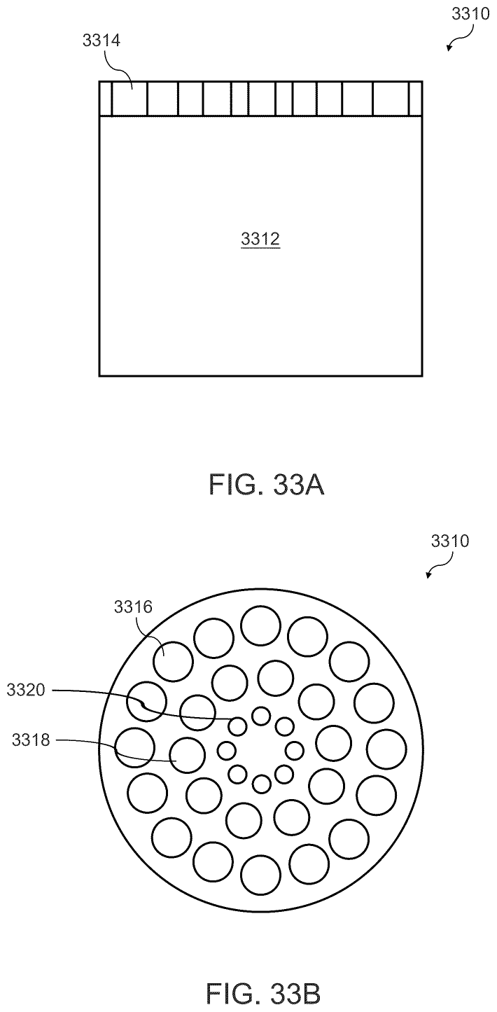

The retention mechanism can be used to contain a source material, particularly when it is formed from multiple separate shaped solids (e.g., spheres). The channels 538 allow sublimated vapor to escape into the main chamber of the reaction crucible where they can reach the seed material or growing crystal. The channels may be designed/located to control the vapor flow within the crucible. For example, they can direct the vapor to specific parts of the seed material or growing crystal. This concept is similar to the filter described below with reference to FIG. 33B. In some embodiments, the channels in the side walls 534 may be omitted so that sublimated vapor can only exit through the channels in the cap 536. In some embodiments, the cap 536 may be omitted, as shown in FIG. 5D. In some embodiments, rather than, or in addition to, channels 538, the source walls and/or cap of the retention mechanism may be made from a highly porous material that the sublimated vapor can escape through.

In some embodiments, it may be desired to restrict vapor flow from either the sides or the top. As such, the sides or top of the retention mechanism may be formed from a material with no or relatively low porosity. The retention mechanism may be formed from graphite, silicon carbide, or any other suitable material. When the retention mechanism is formed from silicon carbide, it may act as an additional solid source structure. The retention mechanism may be sized to fit within the inner walls of the crucible. The retention mechanism may contact the sidewalls of the crucible or may be spaced apart from them, leaving paths for vapor flow radially outward from the retention mechanism.

A top view of another example embodiment of a composite shaped source material is shown in FIG. 5B. The source material 520 includes large spheres 524 surrounding smaller spheres 526. The spheres 524 and 526 are contained by a source retention mechanism 522. This embodiment may be used when it is desired to have a higher SiC vapor flow/pressure in the central portion of the seed/growing crystal and a lower vapor flow/pressure at the edges. This may be desired to slow the crystal growth rate at the edges to avoid the diameter of the crystal expanding over time (i.e., as it extends lower into the crucible) so as to minimize the amount of the crystal that needs to be removed from the boule during wafer production.

The embodiments shown in FIGS. 5A and 5B may also be combined within the same source material. For example, if the sides are relatively blocked off so that the main source of sublimation is from the top of the source material, the source may be designed such that the top portion is arranged in the manner of FIG. 5A and the bottom portion is arranged like FIG. 5B. As such, during the beginning of the crystal growth process, more vapor can flow to the edges of the seed material such that the diameter expands from the diameter of the seed. Then, after the top portion of the source material sublimates, a second portion can be exposed that is arranged like FIG. 5B. At this point, more vapor may flow to the center of the growing crystal so as to maintain a relatively constant diameter for the remainder of the growth process.

It should be understood that in the embodiments shown in FIGS. 4A and 4B and FIGS. 5A and 5B, the spheres are not necessarily perfect spheres. For example, they can be pebble shaped or the like. Further, the same effect can be produced using shaped solids other than spheres. For example, the source may include rods of various diameters.

Similar to the embodiments shown in FIGS. 4A and 4B and FIGS. 5A and 5B, vapor flow characteristics may be influenced by the size and concentration of voids. As such, the arrangement of voids of different sizes within the source material may be designed based on the temperature profile of the crucible or the desired location of vapor flow to the seed/growing crystal.

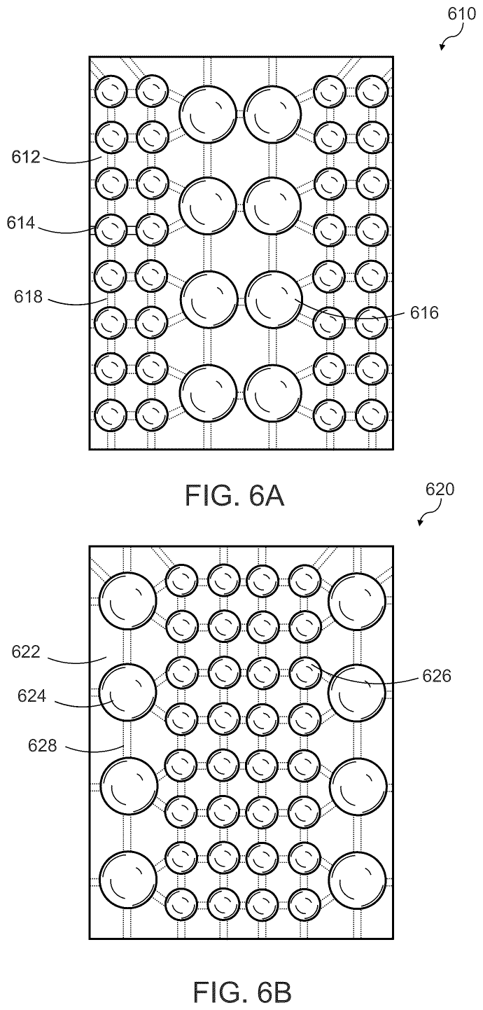

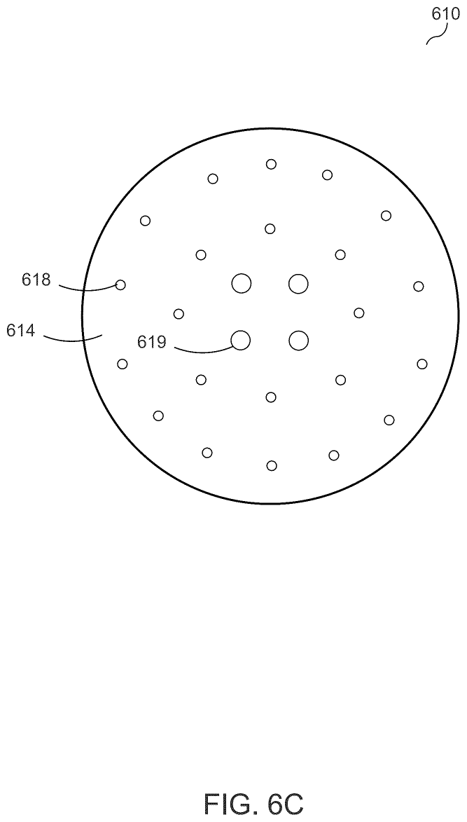

For example, a cross section of another example embodiment of a composite shaped source material is shown in FIG. 6A. The source material 610 includes a cylindrical base 612 with numerous voids, including small voids 614 and large voids 616, formed therein. The large voids 616 are in the center of the cylinder and the small voids 614 radially surround the large voids 616. FIG. 6B shows another embodiment of a source structure 620 that is similar to 610 (FIG. 6A) except that the smaller voids 626 are in the central portion and the larger voids 624 are in the peripheral portion of the cylindrical base 622. As such, the embodiment shown in FIG. 6B may have contrasting sublimation characteristics compared to the embodiment shown in FIG. 6A.

In some embodiments, any voids formed within the source structure may be interconnected. For example, FIG. 6A contains interconnecting channels 618 and FIG. 6B contains interconnecting channels 628. As shown, the channels may connect the voids vertically, horizontally, or on any other angle (e.g., between 10 and 80 degrees with respect to the vertical axis). As shown in FIGS. 6A and 6B, the voids may also be vented through the outer wall of the cylindrical base through channels extending radially outward from the voids. The voids may also be vented out the top and/or bottom of the source structure through channels that extend axially from the voids to the exterior of the structure through the top or bottom surfaces. The voids may also be vented through angled channels (i.e., non-perpendicular and non-parallel to the vertical axis), as shown in in the top sections of FIGS. 6A and 6B. In general, the voids may be interconnected and vented to various locations as desired based on the vapor flow paths desired within the crucible. For example, in some embodiments, the voids may be vented out the sides but not the top. In some embodiments, the voids may be vented out the top but not the sides. In some embodiments, there may be no channels venting the voids to the exterior at all. In some embodiments, various voids may be vented to the exterior but not interconnected with each other.

A top view of the shaped solid source material 610 (show in FIG. 6A) is shown in FIG. 6C. As shown, the channels 618 vent the voids to the top surface of the structure. The channels may be sized based on the desired gas flow rates and thermal gradients. For example, some channels may be larger in diameter than others. As shown in FIG. 6C, for instance, channels 619 are located in the center of the source material structure and are larger than channels 618. In some embodiments, however, the diameters of the channels may all be the same. In other embodiments, channels on the periphery of the source structure may be larger than those in the center.

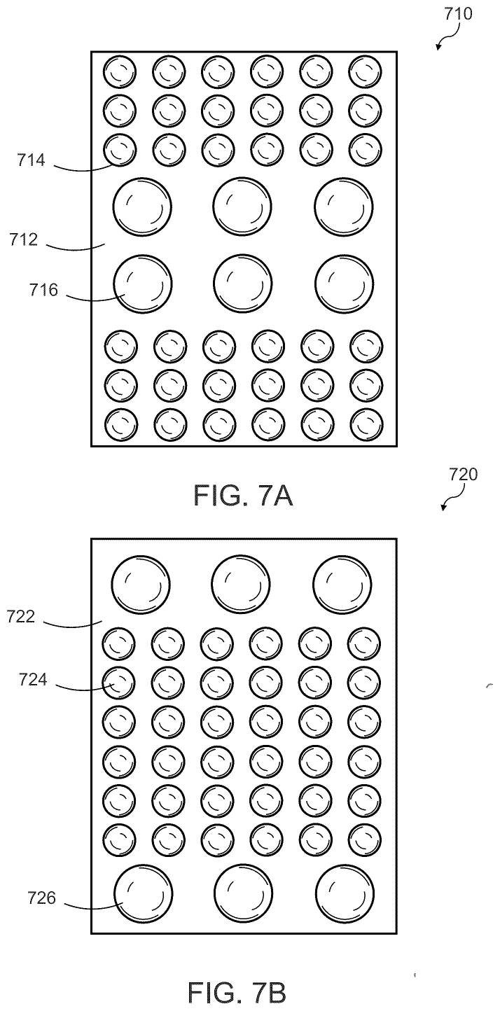

A cross section of another example embodiment of a composite shaped source material is shown in FIG. 7A. The source material 710 includes a cylindrical base 712 with numerous voids, including small voids 714 and large voids 716, formed therein. The large voids 716 are in the center of the cylinder and the small voids 714 are formed above and below the large voids 716. Such a configuration may be used when there is a temperature gradient vertically within the crucible or if it is desired to have various sublimation rates at different times during the growth process. FIG. 7B shows another embodiment of a source structure 720 that is similar to 710 (FIG. 7A) except that the smaller voids 724 are in the central portion and the larger voids 726 are in the upper and lower portions of the cylindrical base 722. As such, the embodiment shown in FIG. 7B may have contrasting sublimation characteristics compared to the embodiment shown in FIG. 7A.

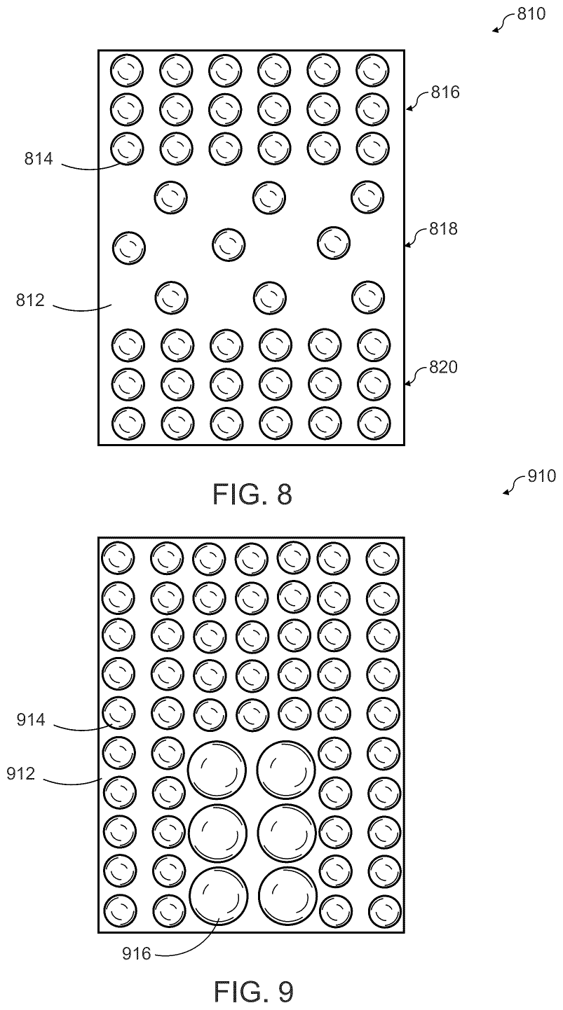

FIG. 8 shows a cross-section of another example embodiment of a composite shaped source material. The source material 810 includes a cylindrical base 812 with numerous voids 814 formed therein. In this embodiment, rather than changing the size of the voids to control the sublimation properties, the concentration of the voids is varied along the height of the cylindrical base 812. For example, the concentration of voids is relatively high at the top portion 816 and the bottom portion 820 and relatively low in the middle portion 818.

FIG. 9 shows a cross-section of another example embodiment of a composite shaped source material. The source material 910 includes a cylindrical base 912 with numerous voids, including small voids 914 and large voids 916, formed therein. The large voids 916 are in the bottom portion of the center of the cylinder and the small voids 914 surround the large voids 916 on all sides except the bottom. Such an embodiment may be used to control the sublimation properties over time. For example, if sublimation is occurring relatively equally across all exposed areas of the surface of the cylinder (the bottom is not exposed as it is against the bottom surface of the crucible), then the outer portions of the source material may sublimate at a first rate during a first phase of crystal growth and then change to a second rate over time as the outer portions sublimate and expose the inner portion having a different void configuration. Alternatively, in other embodiments, the smaller voids may surround the larger voids on the bottom portion too.

It should be understood that in any of the embodiments shown in FIGS. 6A-9, the voids may be interconnected with each other through the use of holes or channels. Further, the embodiments are shown as examples of how sublimation properties and therefore the properties of the growing crystal can be controlled through the shape of the source material. However, other configurations may be designed based on the desired sublimation characteristics.

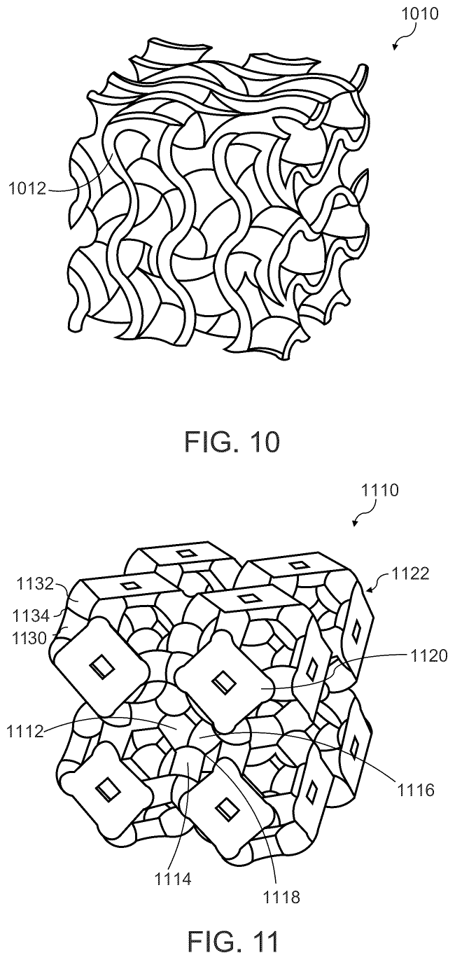

One example embodiment of a composite shaped source material structure is shown in FIG. 10. The structure 1010 is in the shape of a gyroid, which contains many surfaces with inflection points, such as inflection point 1012. The gyroid shape provides tortuous gas paths through the source material, which may influence thermal gradients and sublimation rates. The structure 1010 also has a relatively high surface area which can provide high sublimation rates. If desired, holes or channels may be provided within the surfaces of the structure to improve the thermal performance of the source material (e.g., provide pathways for radiative heat to penetrate to the interior portions of the structure).

Another example embodiment of a composite shaped source material structure is shown in FIG. 11. The structure 1110 is in the shape of a Kelvin structure containing numerous Kelvin unit-like cells. The structure contains multiple substructures. For example, the structure contains many substructures in the form of rods, such as rods 1112, 1114, and 1116 which meet at joint 1118. The structure also contains examples of facets, such as facet 1120, which has a flat surface. Further, each of the unit cells, such as Kelvin cell 1122, are substructures of the larger composite shaped structure 1110. Structure 1110 also includes various curved facets, such as facet 1130 and 1132, which meet at seam 1134. The structure 1110 is an example of a structure which has a high surface area for high sublimation rates. Structure 1110 also provides many pathways for radiative heat to pass through the structure for more a more uniform temperature profile throughout the source material. Further, structure 1110 provides many gas pathways for sublimated SiC to exit the source material structure. Such gas pathways can help prevent the recrystallization and solidification of the sublimated SiC onto the surfaces of the source material structure.

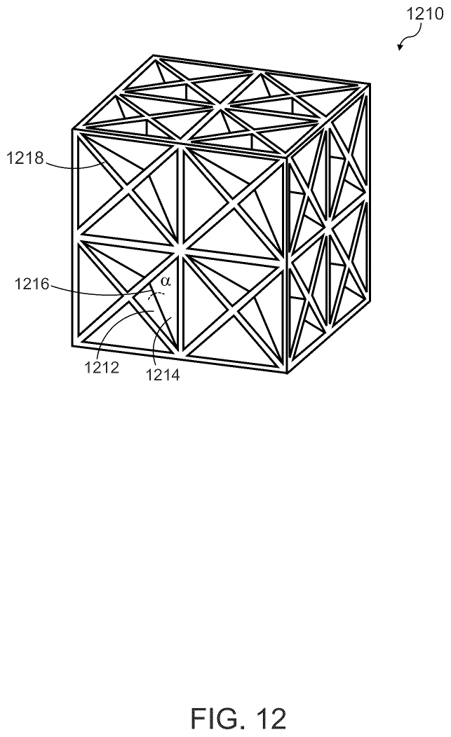

Another example embodiment of a composite shaped source material structure is shown in FIG. 12. The structure 1210 is formed from repeating unit cells in the shape of body centered cubic plates. The structure contains multiple substructures. For example, the structure contains examples of facets, such as planar facets 1212 and 1214, which meet at seam 1216 at angle a. The structure also contains numerous substructures in the form of triangular prisms, such as triangular prism 1218. The structure 1210 has a relatively high surface area which can provide high sublimation rates. If desired, holes or channels may be provided within the surfaces of the structure to improve the thermal performance of the source material (e.g., provide pathways for radiative heat to penetrate to the interior portions of the structure).

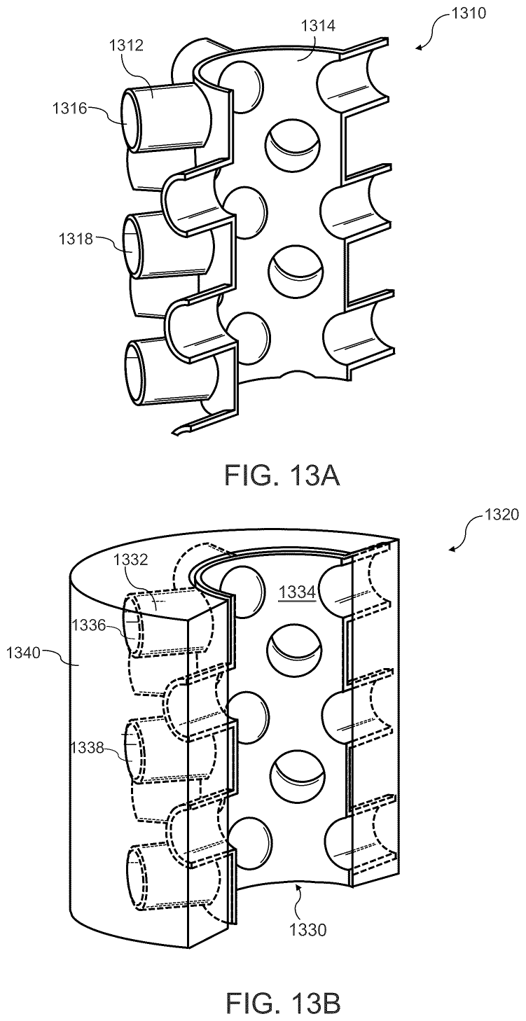

A cross section of another example embodiment of a composite shaped source material structure is shown in FIG. 13A. The structure 1310 contains multiple substructures. For example, the structure contains multiple tubular substructures 1312 projecting outward from a core tubular structure 1314. The structure 1310 also contains numerous channels, such as channels 1316 and 1318. The structure 1310 has a relatively high surface area which can provide high sublimation rates. Structure 1310 also provides many pathways for radiative heat to pass through the structure for more a more uniform temperature profile throughout the source material. Further, structure 1310 provides many gas pathways for sublimated SiC to exit the source material structure. Such gas pathways can help prevent the recrystallization and solidification of the sublimated SiC onto the surfaces of the source material structure.

FIG. 13B shows an example embodiment of a source material structure 1320 including a graphite support 1330 and a shaped solid silicon carbide structure 1340 surrounding the graphite support 1330. The graphite support 1330 contains multiple tubular substructures 1332 projecting outward from a core tubular structure 1334. The graphite support 1330 also contains numerous channels, such as channels 1336 and 1338. As the silicon carbide within he shaped solid silicon carbide structure 1340 sublimates, a portion of the SiC vapor may be evacuated through the tubular structures 1332 and into the core tubular structure 1334 before exiting the source material structure 1320. The use of the graphite support 1330 allows for controlling the flow path of sublimated SiC vapor and provides efficient pathways for the vapor to exit without recrystallizing and solidifying.

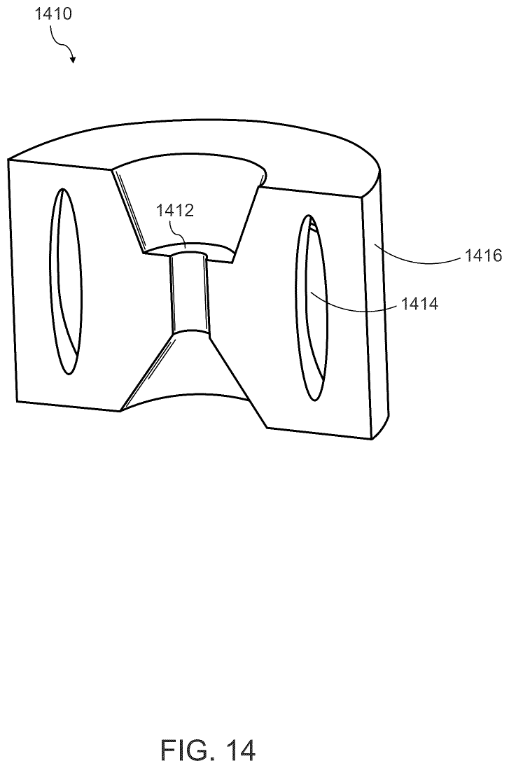

A cross section of another example embodiment of a composite shaped source material structure is shown in FIG. 14. The structure 1410 contains is generally cylindrical with modifications. For example, the structure contains a channel 1412 running from the top surface to the bottom surface of the cylinder. The structure 1410 also contains a void 1414. The structure 1410 is an example of a structure that may provide directionally controlled thermal gradients. For example, heat may flow more efficiently in the axial direction relative to the radial direction, as the outer wall 1416 may act as a barrier to the radiative heat, preventing it from efficiently flowing to inner portions of the structure.

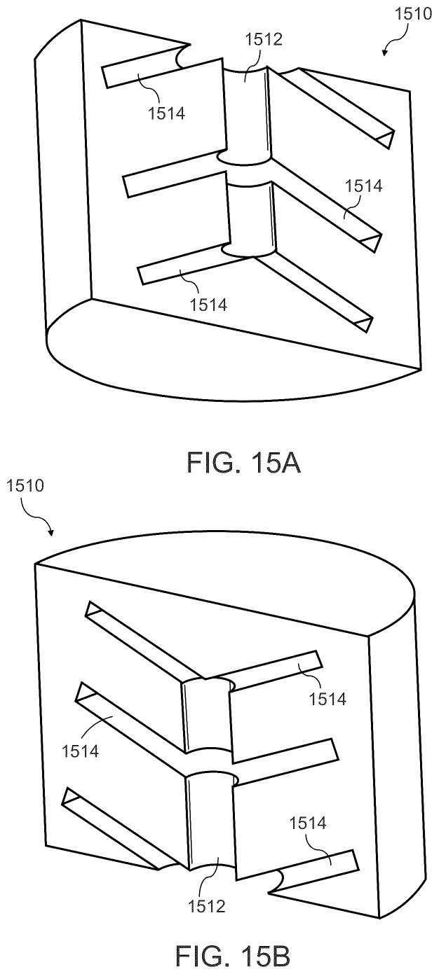

A cross section of another example embodiment of a composite shaped source material structure is shown in FIG. 15A. The structure 1510 is generally cylindrical with modifications. For example, the structure contains a hole 1512 in the bottom surface of the cylinder. The structure 1510 also contains slots 1514. The slots 1514 can help transfer vapor from the surrounding solid regions and into the hole 1512 before exiting the source and passing to the seed material/growing crystal. In another embodiment, the structure 1510 may be flipped such that the hole 1512 faces downward within the reaction crucible, as shown in FIG. 15B. as shown in FIGS. 15A and 15B, the slots 1514 may be angled (i.e., not perpendicular or parallel) with respect to the vertical axis. The angle may be selected based on the shape of the solid source structure and the desired vapor flow paths. In some embodiments, the slots may be perpendicular to the vertical axis.

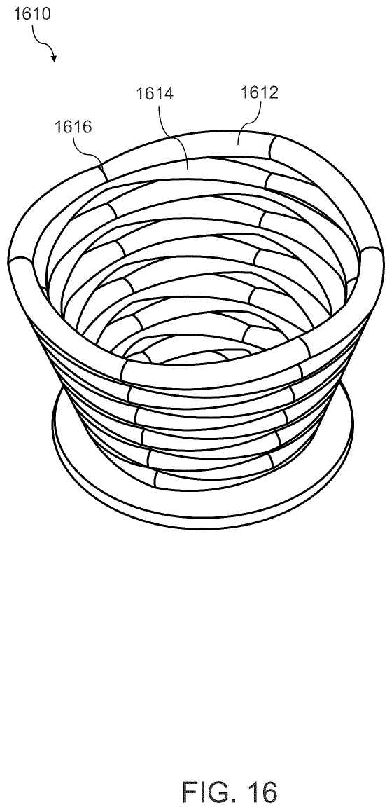

Another example embodiment of a composite shaped source material structure is shown in FIG. 16. The structure 1610 contains multiple substructures. For example, the structure contains multiple curved rods, such as rods 1612 and 1614, which meet at joint 1616. The structure 1610 has a high surface area for high sublimation rates and also provides many thermal and vapor flowpaths.

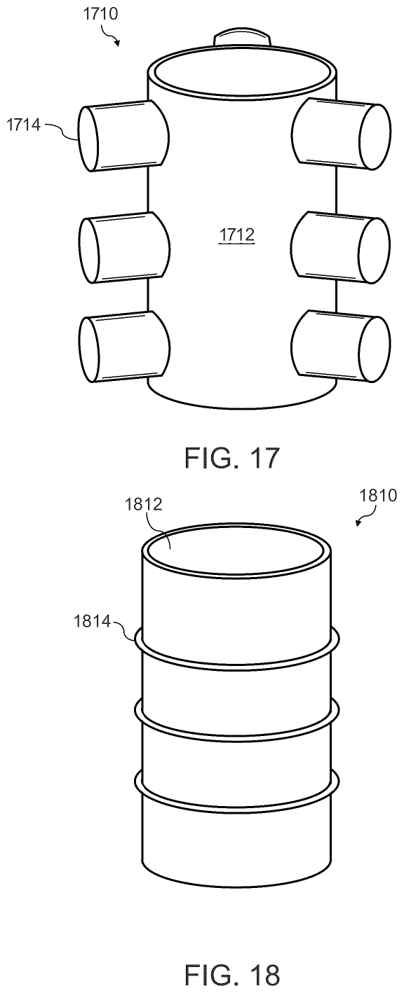

Another example embodiment of a composite shaped source material structure is shown in FIG. 17. The structure 1710 contains a cylindrical core structure 1712 and numerous surface projections, such as pedestal 1714, projecting from the surface of the cylindrical core 1712. The structure is also an example of a composite solid structure containing multiple substructures. For example, the pedestals 1714 and the cylindrical core 1712 are substructures of the composite source material structure 1710. The structure 1710 has high surface area which may provide high sublimation rates.

Another example embodiment of a composite shaped source material structure is shown in FIG. 18. The structure 1810 contains a cylindrical core structure 1812 and numerous surface projections, such as ridge 1814, projecting from the surface of the cylindrical core 1812. The structure is also an example of a composite solid structure containing multiple substructures. For example, the ridges 1814 and the cylindrical core 1812 are substructures of the composite source material structure 1810. The structure 1810 has high surface area which may provide high sublimation rates.

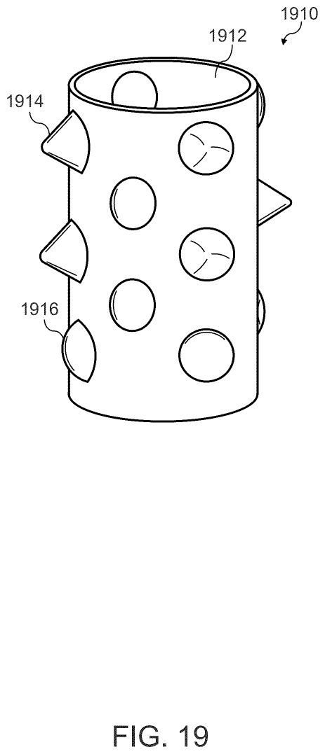

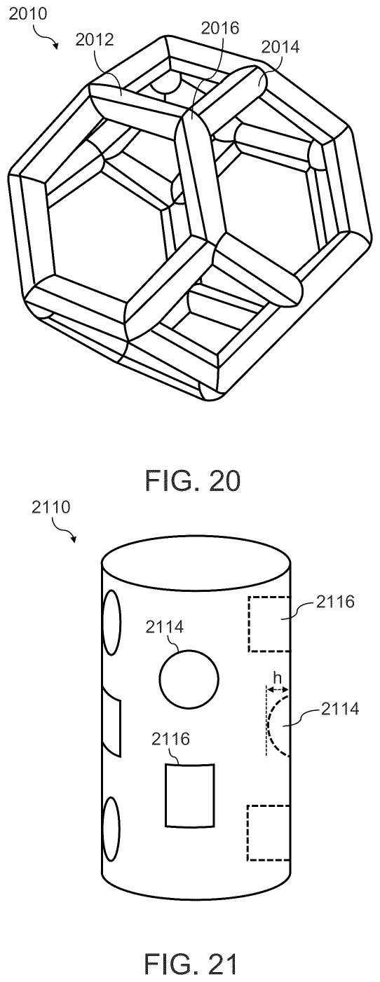

Another example embodiment of a composite shaped source material structure is shown in FIG. 19. The structure 1910 contains a cylindrical core structure 1912 and numerous surface projections, such as peak 1914 and mound 1916, projecting from the surface of the cylindrical core 1912. The structure is also an example of a composite solid structure containing multiple substructures. For example, the peaks 1914, the mounds 1916, and the cylindrical core 1912 are substructures of the composite source material structure 1910. The structure 1910 has high surface area which may provide high sublimation rates. Another example embodiment of a composite shaped source material structure is shown in FIG. 20. The structure 2010 contains multiple substructures. For example, the structure contains numerous interconnected rectangular prisms, such as rectangular prisms 2012 and 2014, which are connected at joint 2016. The structure 2010 has a high surface area for high sublimation rates and also provides many thermal and vapor flowpaths.

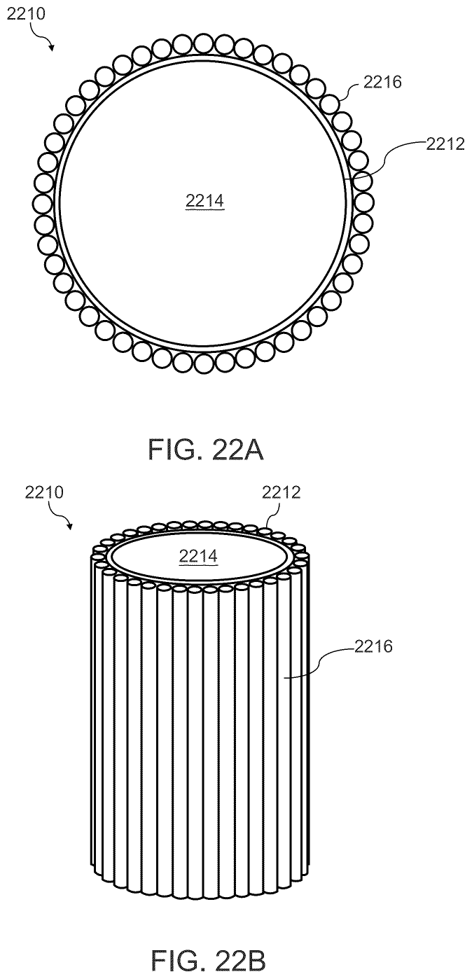

Another example embodiment of a composite shaped source material structure is shown in FIG. 21. The structure 2110 contains a modified cylinder. For example, the structure contains a cylindrical base 2110 and numerous holes, such as holes 2114 and 2116. Hole 2114 has a round perimeter and hole 2116 has a rectangular perimeter. As indicated by h in FIG. 21, the depth of the hole 2114 is measured as the maximum depth of the hole in the direction normal to the surface at its perimeter. The various holes within the structure can provide flowpaths to transport sublimated SiC from the interior of the structure to the exterior so it can flow to the seed material/growing crystal. Further, the holes can provide pathways for radiative heat to reach the interior of the structure.

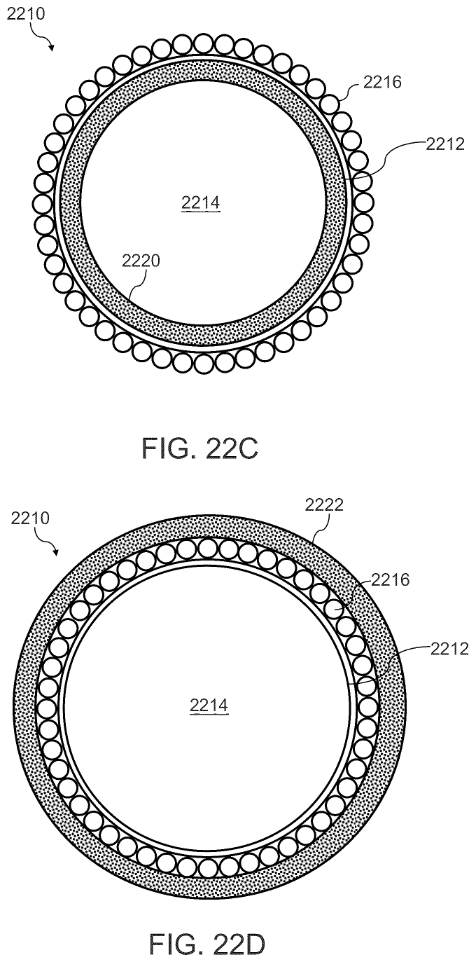

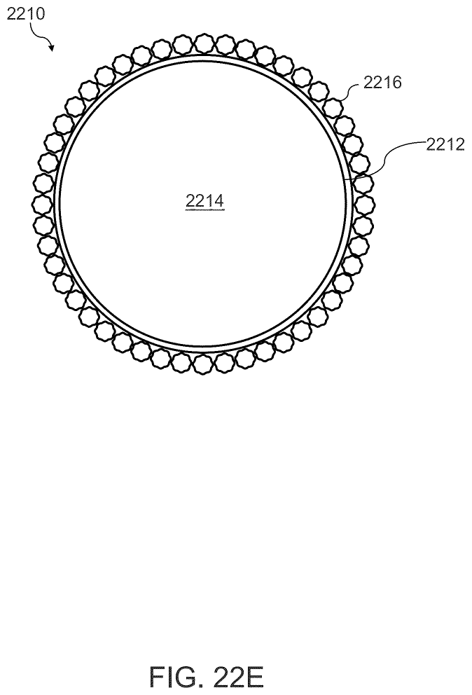

Another example embodiment of a composite shaped source material structure is shown in FIGS. 22A and 22B. FIG. 22A shows a top view of the composite solid structure 2210, which contains a cylindrical base 2212 having a channel 2214 running between its top to bottom surfaces to form a tubular structure. The tubular structure is surrounded by rods 2216. In some embodiments, the rods 2216 may be integral with the cylindrical base 2212. For example, they may be adhered to or monolithic with the cylindrical base 2212. In other embodiments, the rods 2216 are distinct from the cylinder 2212 and are only placed along its perimeter. Such an embodiment is an example of a composite solid structure containing two or more shaped solids. In some embodiments, the rods 2216 may be formed from silicon carbide and the cylindrical base 2212 may be formed from graphite. In other embodiments, the rods 2216 and the cylindrical base 2212 are formed from silicon carbide. FIG. 22B provides a different view of the composite source material structure 2210. The use of multiple rods provides increased surface area for faster sublimation rates.

FIG. 22C shows an embodiment similar to that shown in FIGS. 22A-22B, but with the addition of SiC powder 2220 within the cylindrical base 2212. Similarly, FIG. 22D shows an embodiment similar to that shown in FIGS. 22A-22B, but with the addition of SiC powder 2222 on the outside of the rods 2216.

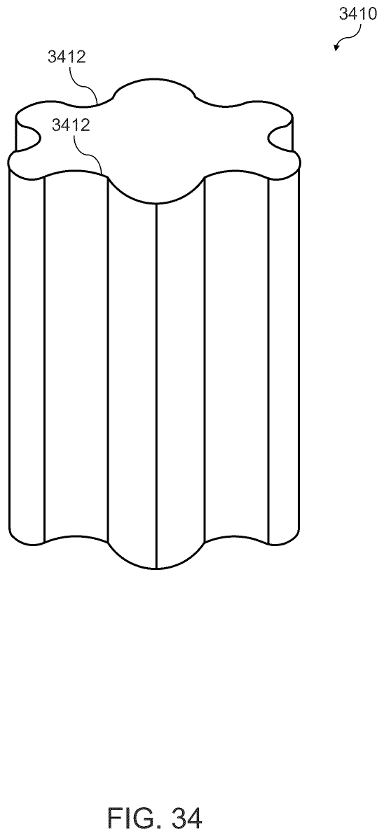

FIG. 22E shows an embodiment similar to that shown in FIGS. 22A-22B, but with the rods 2216 having slots (e.g., of the type shown in FIG. 34). The slots provide the individual rods with even greater surface area for faster sublimation.

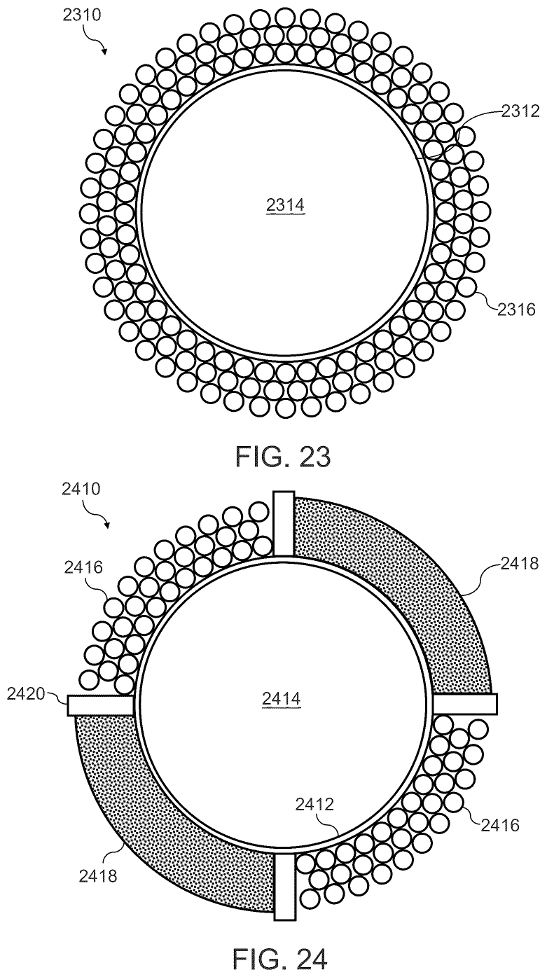

Another example embodiment of a composite shaped source material structure is shown in FIG. 23. The composite solid structure 2310 is similar to that shown in FIG. 22A-22B except that more rods 2316 are placed around the tube formed from cylindrical base 2312 and channel 2314 such that there are multiple rows of rods 2316.

Another example embodiment of a composite shaped source material structure is shown in FIG. 24. The composite solid structure 2410 is similar to that shown in FIG. 23 except that sections of rods 2416 and sections of silicon carbide powder 2418 surround the tube formed from cylindrical base 2412 and channel 2414. In some embodiments, the powder sections 2418 are sintered. The sections of rods 2416 and powder 2418 are separated by dividing walls 2420, which may be integral with or adhered to cylindrical base 2412. For example, in some embodiments, the cylindrical base 2412 and the dividing walls 2420 are formed from silicon carbide, and in other embodiments, they are formed from graphite.

The cylindrical bases 2212, 2312, and 2412 shown in FIGS. 22A-24 can be the same as the retention member shown in FIG. 5D and can have any of the holes, pores, and variations described above with respect to FIG. 5D.

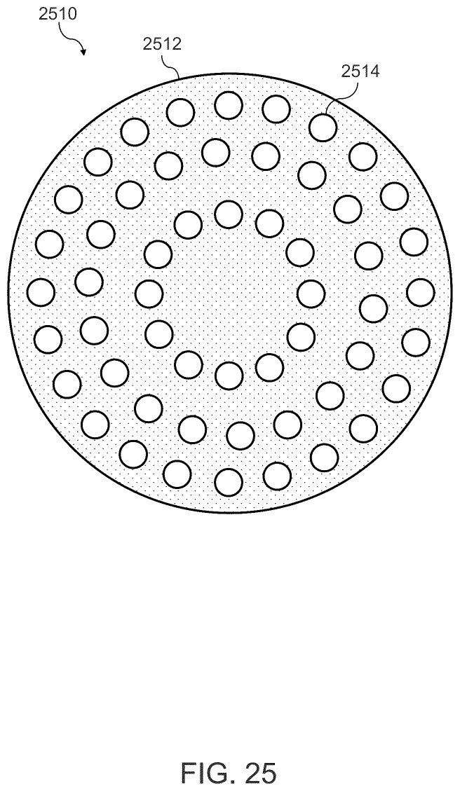

Another example embodiment of a composite shaped source material structure is shown in FIG. 25. The composite solid structure 2510 contains a cylindrical base 2512 modified with channels 2514. In other embodiments, instead of channels, the cylindrical base 2512 may be modified with holes that do not penetrate all the way through the cylindrical base 2512. In some embodiments, the structure 2510 may be a graphite converted silicon carbide structure and the channels 2514 may be strategically placed to allow for good penetration of the silicon-containing gas into the graphite preform, even within the interior volume of the structure. For example, the holes or channels can be placed in a uniform manner to facilitate uniform graphite conversion as well as uniform sublimation properties. Alternatively, the holes or channels may be placed in a non-uniform manner to facilitate non-uniform graphite conversion and non-uniform sublimation properties.

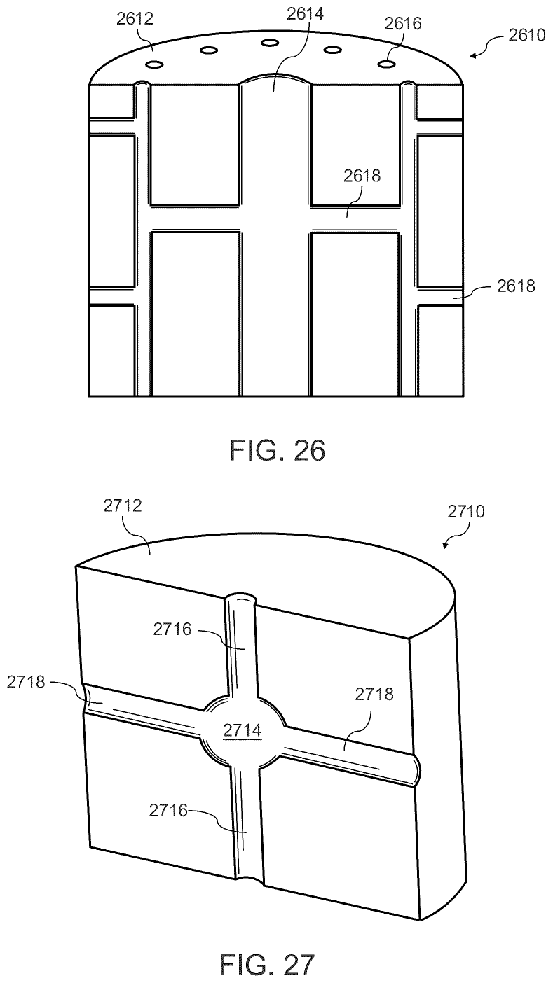

A cross-section of another example embodiment of a composite shaped source material structure is shown in FIG. 26. The composite solid structure 2610 contains a cylindrical base 2612 modified with a network of channels. For example, the structure 2610 contains a central channel 2614 running from the top surface to the bottom surface of the structure 2610.

The structure 2610 also contains peripheral channels 2616 surrounding the central channel 2614 running from the top surface to the bottom surface of the structure 2610. The peripheral channels 2616 are connected to the central channel 2614 and the outer surface of the structure 2610 by horizontal channels 2618. In this regard, FIG. 26 shows an example of a structure containing channels in perpendicular relation to each other. It should be understood that, in other embodiments, peripheral channels 2616 may be connected only to the outer surface of the structure 2610 by horizontal channels 2618 and not to the central channel 2614. Similarly, in some embodiments, the structure may contain peripheral channels 2616 connected to the outer surface of the structure 2610 by horizontal channels 2618 and not contain a central channel, such as 2614, at all. Alternatively, peripheral channels 2616 may be connected only to the central channel 2614 by horizontal channels 2618 and not to the outer surface of the structure 2610. The various channels may be strategically placed to draw silicon carbide vapor from the surrounding solid portions of the source material and direct it as desired.

A cross-section of another example embodiment of a composite shaped source material structure is shown in FIG. 27. The composite solid structure 2710 contains a cylindrical base 2712 modified with a network of channels. For example, the structure 2710 contains an interior cavity 2714 connected to the outside surfaces of the structure 2710 by vertical channels 2716 and horizontal channels 2718. In this regard, FIG. 27 also shows an example of a structure containing channels in perpendicular relation to each other. The various channels may be strategically placed to draw silicon carbide vapor from the surrounding solid portions of the source material and direct it as desired.

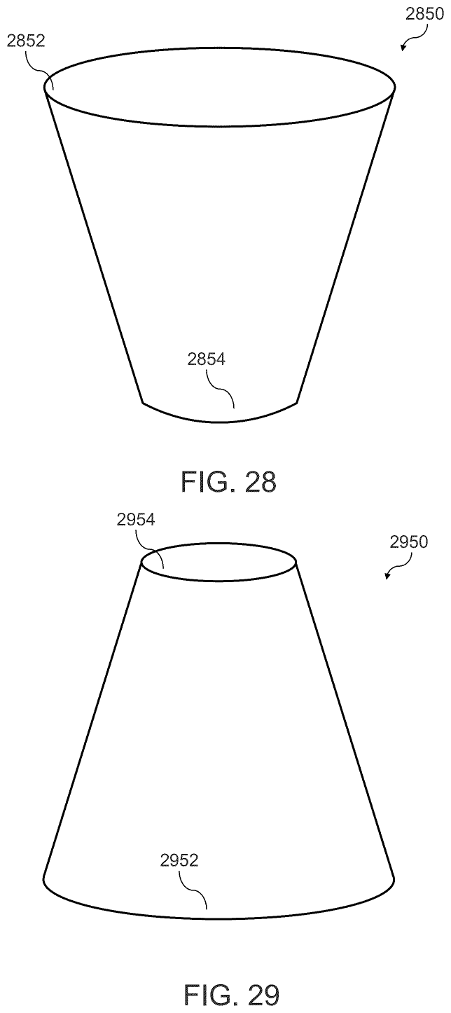

FIG. 28 shows an example embodiment of a source material structure 2850 having a generally conical structure having a wide portion 2852 and a narrow portion 2854. The structure may be strategically placed within the reaction crucible such that the wide portion 2852 is in an area known to be a local hot spot and such that the narrow portion 2854 is in a relatively cooler spot. In this regard, there is more material available for sublimation in the locally hot spot where sublimation may occur faster and less material to sublimate in the relatively cooler spot where the sublimation rate may be slower.

FIG. 29 shows an example embodiment of a source material structure 2950 having a generally conical structure having a wide portion 2952 and a narrow portion 2954. Whereas the structure 2850 in FIG. 28 has a wide upper portion and a narrow lower portion, structure 2950 has a narrow upper portion and a wide lower portion. This structure may be used when the locally hot spot is at the bottom of the reaction crucible.

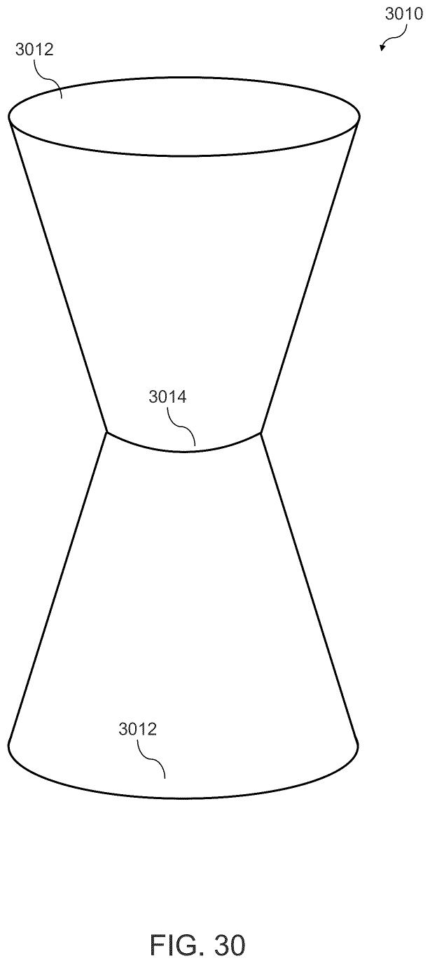

FIG. 30 shows an example embodiment of a source material structure 3010 having an hourglass structure having wide portions 3012 and a narrow portion 3014. The structure may be strategically placed within the reaction crucible such that the wide portions 3012 are in an areas known to be local hot spots and such that the narrow portion 3014 is in a relatively cooler spot.

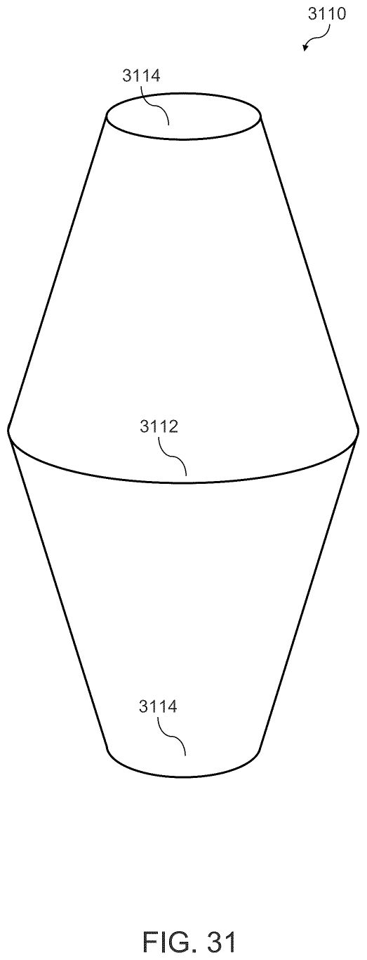

FIG. 31 shows an example embodiment of a source material structure 3110 having a bulging structure having a wide portion 3112 and narrow portions 3114. The structure may be strategically placed within the reaction crucible such that the wide portion 3112 is in an area known to be a local hot spot and such that the narrow portions 3114 are in relatively cooler spots.

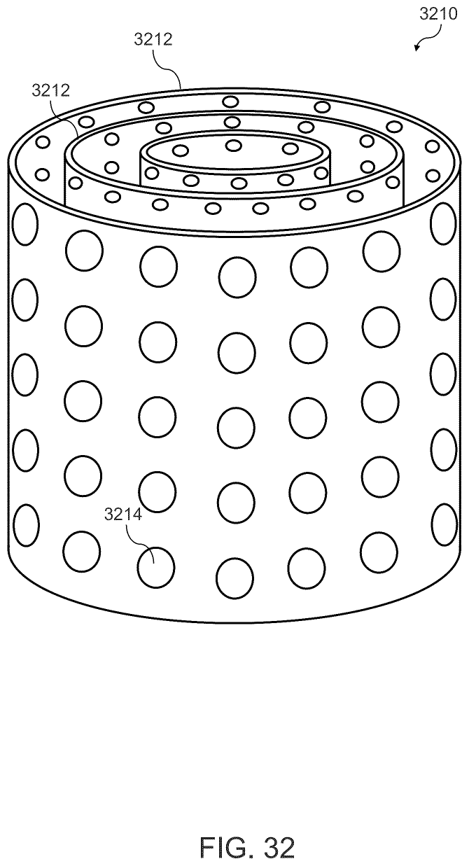

FIG. 32 shows an example embodiment of a structure 3210 containing multiple concentric tubular structures 3212, each containing numerous channels 3214 within their walls. The structure 3210 has a high surface area which may provide fast sublimation rates. The gaps between the various concentric tubular structures 3212 allow for efficient vertical flow of sublimated SiC toward the seed material/growing crystal. The channels 3214 allow for efficient radial flow of heat and/or vapor.

FIG. 33A shows an example embodiment of a structure 3310 containing a shaped solid silicon carbide material 3312 and a graphite filter 3314. FIG. 33B shows a top view of the structure 3310 and shows that the graphite filter has large outer channels 3316, medium-sized channels 3318 in a radially middle portion, and small inner channels 3320. As the silicon carbide sublimates from the shaped solid silicon carbide material 3312, the graphite filter 3314 directs its flow. For example, the progressively wider channels toward the perimeter of the structure may direct more SiC vapor into the periphery of the reaction crucible relative to the central portion. Alternatively, it should be understood that the channels toward the middle of the graphite filter 3314 may be larger than those toward its perimeter to achieve the opposite effect.

In some embodiments, instead of being made from graphite, the filter 3314 may be formed from silicon carbide such that it acts as both a filter and a shaped solid source material. In some embodiments, the filter 3314 may have a higher porosity, particularly open porosity, so that sublimated vapor from structure 3312 can pass through the filter 3314. In this regard, the filter 3314 may not even have channels formed therein. For example, it may be a relatively highly porous puck of graphite or silicon carbide.

FIG. 34 shows an example embodiment of a shaped solid silicon carbide source material structure 3410. The structure 3410 is a modified cylinder having slots 3412 running axially along its perimeter. The slots provide the structure with increased surface area compared to an unmodified cylinder, which can provide faster sublimation rates.

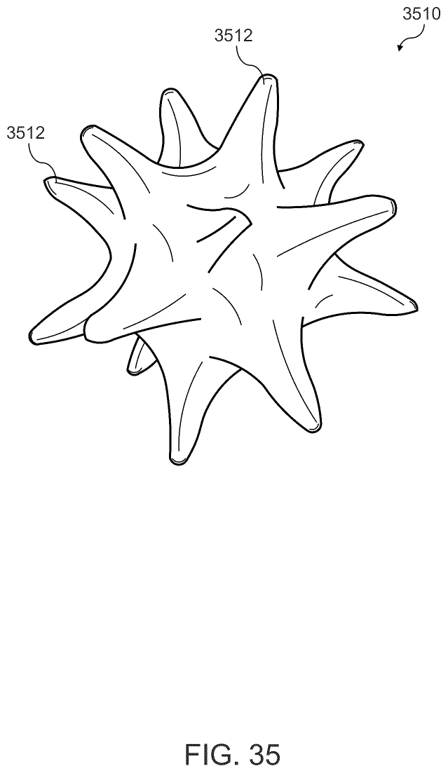

FIG. 35 shows an example embodiment of a shaped solid silicon carbide source material structure 3510. The structure 3510 contains numerous peaks 3512.

In the structures of FIGS. 34 and 35, the specific surface area is radially variable. For example, the specific surface area is higher toward outer portions of the structures compared to the inner portions. This may allow for controlling the sublimation rate over time as the SiC in the outer portions may sublimate faster than the inner portions.

In any of the embodiments described herein, the source material structure contains silicon carbide. The silicon carbide structure can be formed in any suitable manner. For example, in some embodiments, the structure may be formed from silicon carbide powder and optionally a binder. The silicon carbide powder preferably has a median particle size (d50, as determined according to ISO 13320), sometimes referred to as grain size when formed into a solid, of about 5 μm or greater, such as about 10 μm or greater, such as about 15 μm or greater, such as about 20 μm or greater, such as about 30 μm or greater, such as about 50 μm or greater, such as about 70 μm or greater. In some embodiments, the grain size may be about 5 mm or less, such as about 1 mm or less, such as about 200 μm or less, such as about 100 μm or less, such as about 80 μm or less, such as about 60 μm or less, such as about 50 μm or less, such as about 40 μm or less, such as about 30 μm or less, such as about 20 μm or less. Examples of suitable binders include organic binders, such as polyethylene (e.g., HDPE), ethylene vinyl acetate, paraffin wax, organosilicons, preceramic polymers (e.g., polycarbosilane), polyvinylalcohol, acrylic resin, formaldehyde resin, epoxy resin, phenolic resin, polysaccharides, cellulose derivatives, polyethylene glycol, UV curable polymer adhesives, and the like. The binder may also be a sintering aid, such as carbon, aluminum, or boron. In some embodiments, to reduce or eliminate the boron content in the silicon carbide single crystal, boron is not used as a binder. Other suitable binders include, for example, cerium oxide, silicon nitride, and silica. In some embodiments, a binder including a dopant material (e.g., vanadium, boron, aluminum, nitrogen, cerium, germanium, and the like) may be used. For example, if it were desired to include cerium as a dopant in the grown crystal, cerium oxide may be used as a binder or if boron were desired as a dopant, boron carbide may be used as a binder.

The silicon carbide powder and optional binder may be shaped using any suitable method. For example, in some embodiments, it is extruded. In other embodiments, it is cast using a mold. In other embodiments, it is hot pressed (e.g., pressure sintered). The resulting structure may or may not be sintered after it is shaped.

In other embodiments, the silicon carbide structure is a graphite converted silicon carbide structure. Graphite converted silicon carbide can be produced by exposing a graphite preform to a silicon-containing gas, such as silicon monoxide, TEOS, and/or silicon containing vapor, at a high temperature. This method is generally known as the chemical vapor reaction (CVR) process. For example, in one embodiment, a graphite preform having the shape of the desired silicon carbide source material structure is formed by molding, casting, extruding, 3D printing, or the like, and then exposed to silicon monoxide at a high temperature, for example, from about 1400° C. to about 2000° C. The graphite preform may be converted to a silicon carbide structure having essentially the same shape as the graphite preform.

In one example embodiment, when the source material is a graphite converted silicon carbide structure, the graphite preform is a needle coke graphite structure. The graphite preform may have an material density from about 1.1 g/cm³ to about 1.9 g/cm³, such as about 1.4 g/cm³ to about 1.6 g/cm³, an open porosity (open pore volume/total pore volume) from about 90% to 100%, and a grain size from about 1 to about 20 micrometers. Graphite preforms having such properties provide good efficiency of graphite conversion into silicon carbide when exposed to a silicon-containing gas. The material density of the resulting silicon carbide structure may be about 1.4 g/cm³ or more, such as about 1.6 g/cm³ or more, such as about 1.8 g/cm³ or more, such as about 2.0 g/cm³ or more, such as about 2.2 g/cm³ or more, such as about 2.4 g/cm³ or more, such as about 2.6 g/cm³ or more, such as about 2.8 g/cm³ or more, such as about 3.0 g/cm³ or more. The material density may be about 3.1 g/cm³ or less, such as about 3.0 g/cm³ or less, such as about 2.9 g/cm³ or less, such as about 2.8 g/cm³ or less, such as about 2.7 g/cm³ or less, such as about 2.6 g/cm³ or less, such as about 2.5 g/cm³ or less.

When the source material is a graphite converted structure, it may contain some unconverted graphite in addition to the silicon carbide. Similarly, it may contain some unreacted silicon or free silicon.

In another embodiment, the silicon carbide source material structure may be a 3D printed silicon carbide structure. For example, in some embodiments, the source material is 3D printed from a 3D printing composition including SiC powder and a binder.

In some embodiments, the binder may form a non-graphitizable carbon under extreme heat, for example, at pyrolysis temperatures in a range of about 1600° C. to 3000° C. The binder may also have a relatively high char yield. For example, the binder preferably has a char yield of at least 50%, in some embodiments at least 70%, and in some embodiments, at least 90% at pyrolysis temperatures in a range of about 1600° C. to about 3000° C. Examples of suitable binders include furan resin, furfuryl alcohol resin and, UV curable polymer adhesives, and supramolecular organometallic curable fluids.

The UV curable polymer adhesives may comprise one or more photosensitive monomers or oligomers capable of being polymerized by UV light.

The UV curable polymer adhesive can be a commercial photopolymer or a photopolymer formulated by mixing monomers, oligomers, photoinitiators, and other additives such as photo-absorbers, dyes, and inhibitors. The monomer/oligomer can be (but is not restricted to) an acrylate-based monomer, an acrylamide-based monomer, a polyether, an acryloyl morpholine, a polyethylene glycol, an epoxy-based monomer, or a combination of these and other monomers.

Examples of acrylate-based monomers are acrylates (e.g., behenyl acrylate, or 2-hydroxyethyl acrylate), diacrylates (e.g., polyethylene glycol diacrylate), triacrylates (e.g., trimethylolpropane triacrylate), tetraacrylates (e.g., di(trimethylolpropane) tetraacrylate), and methacrylates (e.g., (hydroxyethyl)methacrylate).

An example of a polyether is polypropylene glycol.

Examples of acrylamide-based monomer are acrylamide, and N,N′-methylenebisacrylamide.

An example of an epoxy-based monomer is epoxy cyclohexane carboxylate.

In some embodiments, the UV-curable resin may comprise one or more photosensitive acrylate or methacrylate monomers or oligomers.

The photoinitiator can be (but is not restricted to) peroxides (e.g. benzoyl peroxide), nitrogen dioxide, camphorquinone, molecular oxygen, azobisisobutyronitrile, lithium phenyl-2,4,6-trimethylbenzoylphosphinate, benzoin methyl ether, 2,2-dimethoxy-2-phenylacetophenone, 2-hydroxy-2-methylphenylpropane-1-one, a-hydroxy-acetophenone, bis(2,6-dimethoxybenzoyl)-2,4,4-trimethylpentylphosphine oxide, 2-hydroxy-2-methyl-1-phenyl-propan-1-one, 2,4,6-trimethylbenzoyldiphenylphosphine oxide, or a combination of these and other photoinitiators.

Suitable photoinitiators may be selected from the group consisting of 2,2-dimethoxy-2-phenylacetophenone, 2-hydroxy-2-methylpropiophenone, camphorquinone, bis(2,4,6-trimethylbenzoyl)-phenylphosphineoxide, benzophenone, benzoyl peroxide, dicumyl peroxide, 2,2′-azobisisobutyronitrile, oxygen, nitrogen dioxide, and combinations or derivatives thereof. Other photoinitiators or thermal free-radical initiators may also be utilised.

In some embodiments, the photoinitiator is present from about 0.001 wt. % to about 15 wt. % of the UV-curable polymer. In various embodiments, the photoinitiator may be present in an amount from about 0.002 to about 10 wt. %, from about 0.01 to about 5 wt. %, or from about 0.1 to about 3 wt. % of the binder.

Depending on the 3D printing method used, the binder or a precursor thereof can be combined with the SiC powder prior to the 3D printing process or, alternatively, the binder can be added to the SiC powder during the printing process (e.g., a binder jet process). In some embodiments, the binder is combined with the SiC powder in the form of a similarly sized powder. In other embodiments, the binder is added to the SiC powder in liquid form and then cured into a solid during the 3D printing process.

The part can be 3D printed from a 3D printing composition as described above using known 3D printing techniques. Some examples of suitable 3D printing techniques are described below.

In some embodiments, the 3D printed part is produced through a powder bed 3D printing process. Powder bed fusion processes generally refer to processes where a powder is selectively sintered or melted and fused, layer-by-layer to produce a three-dimensional article. In one embodiment, the powder bed fusion process includes one or more lasers in a process known as laser sintering. During laser sintering, a laser is used to provide a pattern and heat to cause the binder particles to fuse or sinter together in a predetermined way. In addition to using one or more lasers as the heat source, powder bed fusion can also be achieved through the use of other forms of electromagnetic radiation, including, for example, infrared radiation, microwave energy, radiant heating lamps, and the like. The heat source can be coherent or incoherent. When using an incoherent heat source, a mask can be used in order to produce a three-dimensional article according to a particular pattern.

Three-dimensional articles formed through powder bed fusion include a plurality of overlying and adherent sintered or melted layers made from a 3D printing composition. For instance, the three-dimensional article can be made from more than about 8 layers, such as more than about 10 layers, such as more than about 15 layers, such as more than about 20 layers, such as more than about 25 layers, such as more than about 30 layers, such as more than about 40 layers, such as more than about 50 layers, and generally less than about 200,000 layers, such as less than about 150,000 layers. The number of layers can depend upon the particular application and the size of the final product.

In some embodiments, a powdered 3D printing composition is spread over a forming surface. A heat source, such as one or more laser beams, moves relative to the powder bed for producing a pattern in the particles. In one embodiment, the pattern is computer-controlled. In order to produce the pattern, the one or more lasers can move and scan over the forming surface, the forming surface can be moved relative to the lasers, or both the forming surface and the laser can be moved simultaneously. After one layer of powder has been sintered or melted together, another layer of powder is added to the forming surface and sintered or melted repeating the process. The process repeats as the one or more lasers melt and fuse each successive layer to the previous layer until a three-dimensional article is formed.

In some embodiments, the 3D printing composition of the present disclosure is used in a multi-jet fusion process. During multi-jet fusion, different components are combined with the powder during the printing process. For example, during a multi-jet fusion process, the powder is applied in patterns similar to the process described above. In addition to applying the powder, however, a fusing agent (e.g., one of the binders described above or a curing promoter for such a binder) can also be selectively applied to the particles that are to fuse together. In addition, optionally a detailing agent can be applied selectively where the fusing action of the particles needs to be reduced or amplified. For example, the detailing agent can be used to reduce fusing at the boundary to produce a part with sharp or smooth edges. During multi-jet fusion, the three components can be applied in sequence and repeatedly to build up layers and form a part or article.

During the three-dimensional printing process, various properties of the powder composition assist in producing a product having the desired characteristics. For example, the powder composition made up of the particles is preferably flowable. The powder composition should also be sinterable, meaning that the individual binder particles can bond together through thermal bonding or other suitable means. Consequently, formulating a 3D printing composition so as to have a larger operating window can facilitate particle-to-particle bonding and layer-to-layer bonding.

The powder composition, in one embodiment, can be incorporated into a printer cartridge that is readily adapted for incorporation into a three-dimensional printer system. The printer cartridge can include a dispensing container contained within a housing. The dispensing container can be for feeding the powder composition into the three-dimensional printer system.

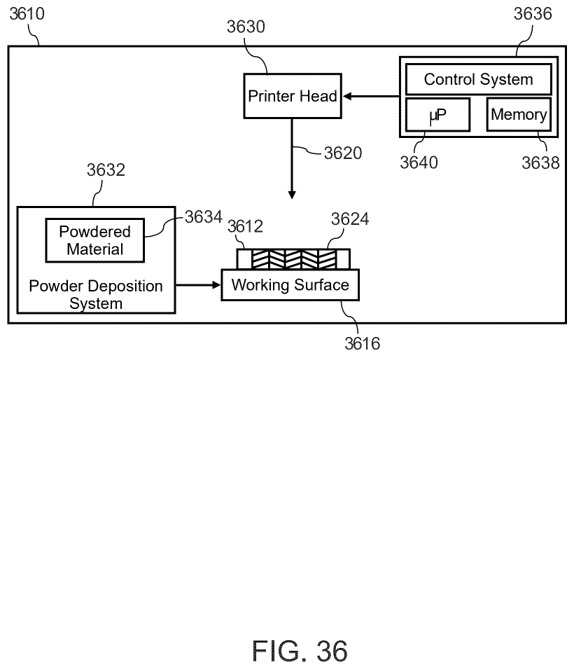

With reference to FIG. 36, an embodiment of a fusion bed printing system is shown. The printing system 3610 comprises a functional platform 3616 providing support for a layer of powder 3612. Additionally, the system 3610 incorporates a powder deposition system 3632 responsible for depositing a powder composition 3634, as disclosed herein, onto the working platform 3616 to create the layer of powder 3612.

The three-dimensional printing system 3610 includes a printer head 3630 emitting an energy source 3620 onto the powder 3612 and the working surface 3616. The printer head 3630 includes, for example, one or more lasers or alternative energy sources. For example, the energy source may also be a binder as described herein or a curing agent for a binder precursor that is already contained in the powdered material 3634.

Communication with a control system 3636 is established for governing the printer head's operation. The control system 3636, which may involve a distributed control system or a computer-based workstation, either fully or partially automated, encompasses memory circuitry 3638 storing instructions for controlling the printer head 3630. In some examples, the memory 3638 holds CAD designs dictating the formation of a three-dimensional article 3624 on the working surface 3616. Comprising one or more processing devices, such as a microprocessor 3640, the control system 3636 utilizes memory circuitry 3638 consisting of tangible, non-transitory, machine-readable media collectively storing instructions executable by the processing device 3640, facilitating the production of three-dimensional articles using the printer head 3630.

As depicted in FIG. 36, during the printing process, the powder 3612 can undergo heating to achieve a molten state to fuse the binder with the ceramic powder. Alternatively, the binder can be selectively cured by a chemical agent to fuse the binder and the ceramic powder particles together. The individual particles undergo fusion, sintering, or bonding with the binder, and the three-dimensional article 3624 is formed in a layer-by-layer fashion, with each successive layer thermally or chemically bonding together.

As previously described, in some embodiments, the powder 3612 is deposited onto the working platform 3616. The layer of particles is then combined with a binder selectively applied in a specific pattern. Optionally, a detailing agent may also be applied to the particles following a prescribed pattern. Subsequently, energy is applied to facilitate the formation of a layer of the article.

Various other three-dimensional printing techniques, such as extrusion-based systems (e.g., fused deposition modeling) and electrophotography, may be employed. For instance, in a fused deposition modeling system, the 3D printing composition may function as a build material forming the three-dimensional structure and/or a support material removed from the structure post-formation.

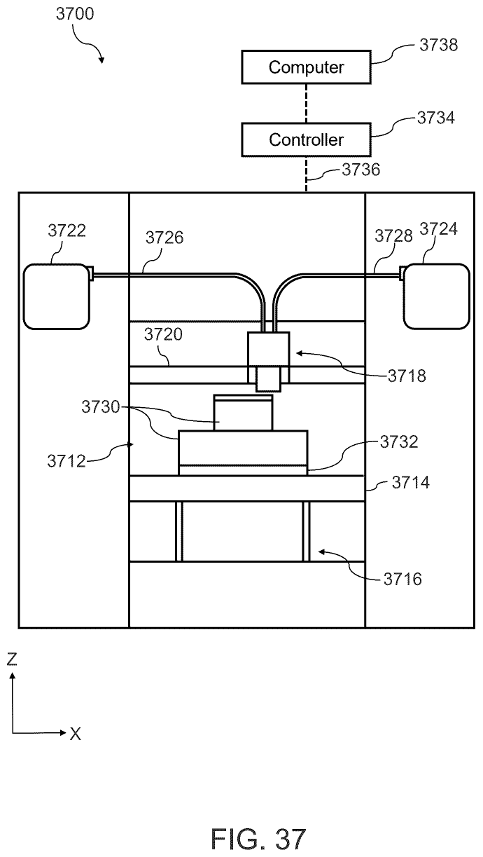

Referring to FIG. 37, an embodiment of an extrusion-based three-dimensional printer system 3700 is illustrated. This system selectively forms a precursor object containing a three-dimensional build structure 3730 and a corresponding support structure 3732 within build chamber 3712. The 3D printing composition described herein may be employed to form the build structure 3730. Conventional materials may be employed for the support structure 3732.

The system 3700, including a controller 3734, is equipped with a nozzle 3718 for printing the build structure 3730 and support structure 3732 on a substrate 3714. The nozzle 3718 is attached to a head frame 3720 allowing it to move side-to-side and front-to-back (i.e., in the X and Y directions). The nozzle 3718 is connected to a build material reservoir 3722 via a build material supply line 3726 and a support material reservoir 3724 via a support material supply line 3728. The controller 3734 communicates with the printing components via communication line 3736 to monitor and operate the system components and may communicate with a computer 3738 to transmit instructions for the selective formation of three-dimensional structures.

The build structure 3730 is constructed layer-by-layer. In this regard, the build structure 3730 is built on a build platform 3714 which is moved vertically via support structures 3716 (i.e., in the Z direction).

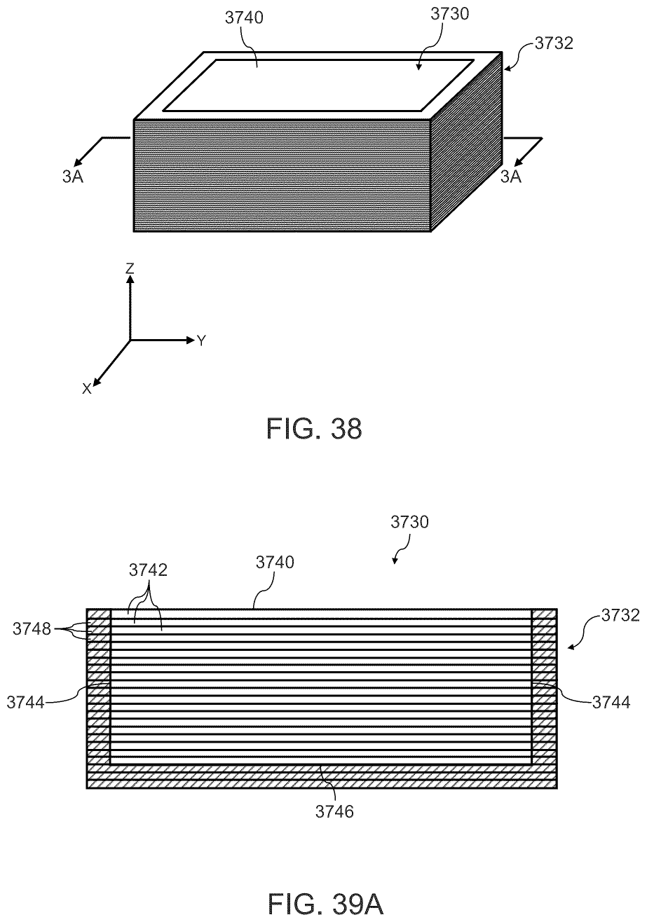

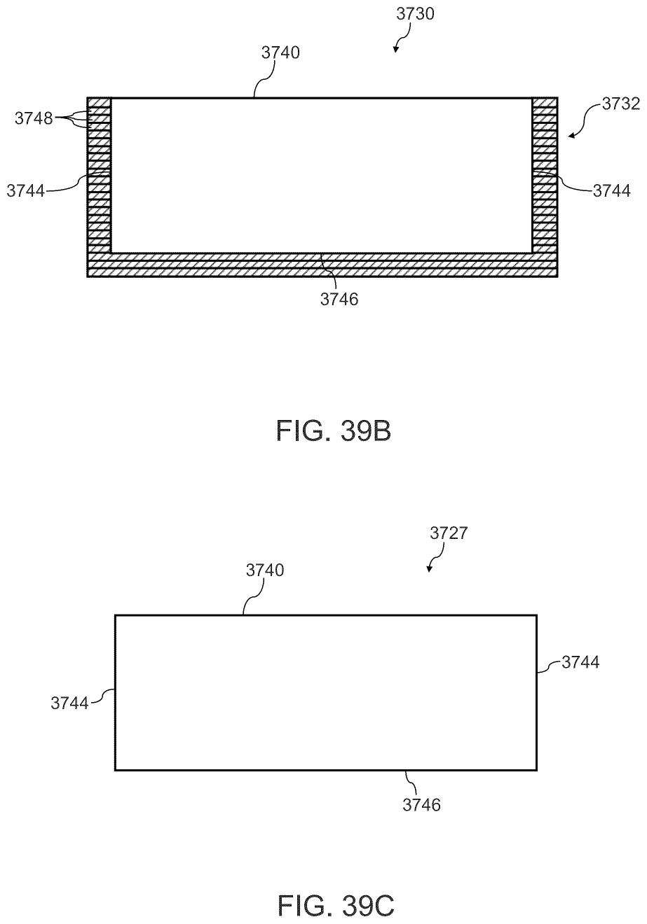

As shown in FIG. 38, the build structure 3730 is printed onto the substrate 3814 in successive layers of the build material, while the support structure 3732 is concurrently printed in successive layers, coordinating with the build structure 3730. The illustrated embodiment presents the build structure 3730 as a simple block-shaped object, featuring a top surface 3740, four lateral surfaces 3744 (FIG. 39A), and a bottom surface 3746 (FIG. 39A). While not obligatory, the support structure 3732 in this embodiment is deposited to partially encapsulate the layers of the build structure 3730. For instance, the support structure 3732 may be printed to encapsulate the lateral surfaces and the bottom surface of the build structure 3730. It should be noted that the system 3710 may print three-dimensional objects with various geometries in alternative embodiments. In such cases, the system 3710 may also print corresponding support structures, optionally partially encapsulating the three-dimensional objects.

FIGS. 39A-39C provide insight into the process of printing the three-dimensional build structure 3724 and support structure 3732 as described above. As depicted in FIG. 39A, each layer of the build structure 3730 is printed in a series of layers 3742 to define the geometry of the build structure 3730. In this particular embodiment, each layer of the support structure 3732 is printed in a series of layers 3748, coordinating with the printing of layers 3742 of the three-dimensional build structure 3730. The printed layers 3748 of the support structure 3732 encapsulate the lateral surfaces 3744 and the bottom surface 3746 of the build structure 3730, while the top surface 3740 remains unencapsulated by the layers 3748 of the support structure 3732. Upon completion of the print operation, the support structure 3732 can be removed from the build structure 3730, resulting in the creation of a three-dimensional object 3727. For instance, in embodiments where the support material is at least partially soluble in water or an aqueous alkaline solution, the resulting object may undergo immersion in a water and/or aqueous alkaline solution bath to dissolve the support structure 3732.

The use of 3D printing methods, including those described above, allows for the production of complex structures that could not be produced, or would be very difficult to produce by conventional methods.

Following 3D printing using any suitable method, including those described above, the resulting green component can undergo sintering, for example, by heating to a temperature of about 1500° C. or more.

In some embodiments, instead of 3D printing silicon carbide directly, a graphite precursor can be 3D printed and then converted to silicon carbide by the CVR process mentioned above. In such embodiments, the 3D printing composition can contain graphite particles instead of silicon carbide particles.

In some embodiments, one or more components of the grower may also be 3D printed. For example, at least a portion of the crucible 114, seed holder 124, source material holder 130, inlet 220, foamed structure 350, or insulation material 118 can be 3D printed. When such components are 3D printed, they may be formed from graphite or a ceramic material which may or may not contain SiC. When a source retention mechanism is contained, it may also be 3D printed, for example, from SiC and used as a secondary source material or from graphite or another ceramic material.

In some embodiments, the shaped source material structure also contains a dopant. For example, suitable dopants include vanadium, aluminum, and boron. The dopant may be incorporated into the shaped solid source by mixing it with the silicon carbide powder and binder prior to forming the shaped structure. Alternatively, if the graphite conversion method is used, the dopant can be incorporated into the graphite precursor structure. In some embodiments, the dopant may be coated or annealed onto a carbon material (e.g., carbon black or graphite particles), which is then mixed with the silicon powder or incorporated into the graphite preform.

In some embodiments, a base silicon carbide structure is formed, for example, by any of the methods described above and then machined to produce the final source material structure. For example, in some embodiments, a silicon carbide base structure (e.g., a cylindrical structure) may be formed and then one or more holes, channels, slots, or the like may be drilled or otherwise machined from the base structure.

Regardless of the formation method, the resulting source material structure may have properties which enhance the sublimation process. For example, the shaped solid structure may have a material density (i.e., skeletal density) from about 1.0 g/cm³ to about 3.21 g/cm³, such as from about 1.4 g/cm³ to about 3.2 g/cm³, such as from about 2.0 g/cm³ to about 3.1 g/cm³, such as from about 2.5 g/cm³ to about 3.0 g/cm³. The apparent density of the source material structure may be from about 1.0 g/cm³ to about 3.21 g/cm³. The shaped solid structure may have an total porosity of about 5% or greater, such as about 10% or greater, such as about 20% or greater, such as about 30% or greater, such as about 40% or greater, such as about 50% or greater, such as about 60% or greater, such as about 70% or greater, and about 90% or less, such as about 80% or less, such as about 70% or less, such as about 60% or less, such as about 50% or less, such as about 40% or less. The shaped solid structure may have a ratio of open porosity to total porosity of about 0.5 or more, such as about 0.6 or more, such as about 0.7 or more, such as about 0.8 or more, such as about 0.9 or more. The combination of grain size, total porosity, open porosity, and density may be selectively controlled such that the solid source material exhibits high sublimation activation.

The solid source material, including source retention mechanisms such as those shown in FIGS. 5C and 5D, may also have portions with varying properties. For example, a solid source material may contain one portion with a first porosity and another portion with a second porosity different from the first porosity. For example, the second porosity may differ by about 1% or more, such as 2% or more, such as 3% or more, such as 5% or more, such as 7% or more, such as 10% or more, such as 15% or more, such as 20% or more, such as 25% or more such as 30% or more, such as 40% or more, such as 50% or more from the first porosity. Such porosities may refer to total porosity or percentage of open porosity. Other properties, such as density and grain size may similarly vary in different portions of the solid source material.

Further, the complexity of the shaped source material may provide it with a relatively high surface area. For example, the ratio of the surface area of the shaped solid to the volume of the shaped solid may be greater than 2 cm⁻¹, such as about 2.1 cm⁻¹ or greater, such as about 2.5 cm⁻¹ or greater, such as about 3.0 cm⁻¹ or greater, such as about 3.5 cm⁻¹ or greater, such as about 4.0 cm⁻¹ or greater, such as about 4.5 cm⁻¹ or greater, such as about 5 cm⁻¹ or greater, even when, for example, the shaped solid has a length of at least 20 mm in a first direction and a length of at least 10 mm in a direction orthogonal to the first direction, or even when the volume of the shaped solid is 30 cm³ or more. Similarly, the shaped structure may have a relatively small volume relative to the space it takes up in the reaction crucible. For example, a ratio of the volume of the shaped structure to the volume of the smallest right cylinder that would fully contain the shaped solid structure may be less than 1, such as about 0.9 or less, such as about 0.8 or less, such as about 0.7 or less, such as about 0.6 or less, such as about 0.5 or less, such as about 0.4 or less, such as about 0.3 or less, and about 0.2 or more, such as about 0.5 or more. Similarly, when source density is defined as mass [g] per volume of the of the smallest right cylinder that would fully contain the shaped solid structure [cm³], the ratio of source density to material density of the source may be less than 1, such as about 0.9 or less, such as about 0.8 or less, such as about 0.7 or less, such as about 0.6 or less, such as about 0.5 or less, such as about 0.4 or less, such as about 0.3 or less, and about 0.2 or more, such as about 0.5 or more. The total volume of the source material may be determined based on the density of the source material and the desired total volume of the crystal that will be grown.

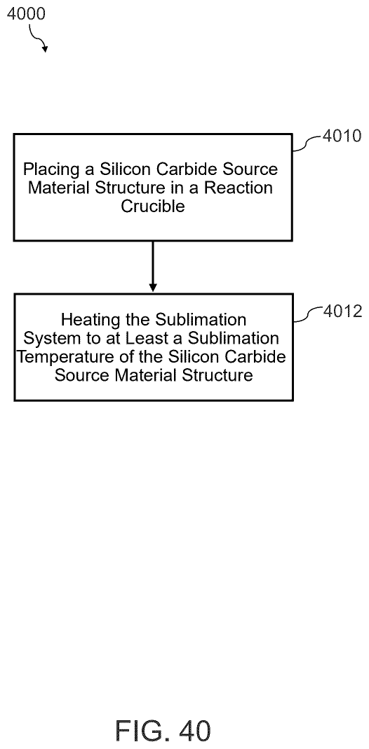

FIG. 40 depicts a flow chart diagram of an example method 4000 according to example embodiments of the present disclosure. FIG. 40 depicts example method steps for purposes of illustration and discussion. Those of ordinary skill in the art, using the disclosures provided herein, will understand that the methods described in the present disclosure may be adapted, modified, include steps not illustrated, omitted, and/or rearranged without deviating from the scope of the present disclosure.

In general method 4000 is a method for growing a single-crystal of silicon carbide (SiC crystal) using a physical vapor transport (PVT) process in a sublimation system. At (4010), method 4000 may include placing a source material containing silicon carbide in a reaction crucible. The source material comprises the shaped solid structure described herein.

At (4012), method 4000 may comprise heating the sublimation system to at least a sublimation temperature of the silicon carbide source material structure. For example, a typical SiC sublimation process is described as follows. However, those familiar with the growth of crystals, particularly in difficult material systems such as silicon carbide, will recognize that the details of the given technique can vary depending on relevant circumstances.

Typically, growth pressure during an applied PVT process will range from about 0.1 to 400 Torr, and more typically between 0.1 and 100 Torr. The process temperature will range from about 2000° C. to about 3000° C. and in some embodiments, from about 2000° C. to about 2500° C. These conditions may vary due to differences in the sublimation system being used and variations in the seeded sublimation growth process being run. The thermal gradient between the growing crystal and the source material is typically controlled in a range of about 50 to 150° C./cm. A sublimating SiC species flux during the process period may be controlled by a ramped increase in the growth temperature in the range of 0.3 to 10° C./hr.

The sublimation process may include the steps of first evacuating the environment around the reaction crucible to remove ambient air, gaseous impurities and extraneous solid particulates. Then, the reaction crucible may be placed under pressure using one or more inert gas(es). Then, the sublimation system may heat the reaction crucible environment to a temperature enabling SiC crystal growth via PVT. Once this temperature is reached, the pressure within the sublimation system may be reduced to a point sufficient to initiate SiC crystal growth. In some embodiments, one or more carrier gasses (e.g., H₂, CH₄, Cl) may be used to increase growth rate or control the ratio of Si to C in the vapor.

In certain embodiments of the present disclosure, one or more type of dopant atoms may be intentionally introduced into sublimation system during or before the seeded sublimation process. For example, one or more dopant gases may be introduced into the seeded sublimation environment and thereby incorporated into the growing SiC crystalline boule. Dopants may be selected for their acceptor or donor capabilities in accordance with the conductivity properties desired for the resulting SiC boule. For certain semiconductor devices, donor dopants produce n-type conductivity and acceptor dopants produce p-type conductivity. Some commonly incorporated n-type dopants include N, P, As, Sb, and/or Ti. Some commonly incorporated p-type dopants include B, Al, Ga, Be, Er, and/or Sc.

With reference again to FIG. 1, in a typical sublimation growth process according to some embodiments, an electrical current having a defined frequency to which the material (e.g., carbon) forming reaction crucible 114 will respond is passed through induction coils 116 to heat reaction crucible 114. The amount and placement of insulation material 118 are selected to create a thermal gradient between a source material 120 and a seed material 122. Reaction crucible 114 is heated with source material 120 to a sublimation temperature (e.g., above about 2000° C.). In this manner, a thermal gradient is established such that the temperature of seed material 122 and the SiC crystalline boule growing on the seed material 122 remains slightly below the temperature of source material 120. In this manner, certain vaporized species generated from the sublimating SiC source (e.g., Si, Si₂C and/or SiC₂) are thermodynamically transported first to seed material 122 and thereafter to the growing SiC crystalline boule (or “the SiC crystal”). The SiC crystal may have a 4H crystal structure, 6H crystal structure, 3C crystal structure, or other crystal structure, depending on the seed material used.

Once the SiC crystal has reached a desired size, the crystal growth process may be terminated by reducing the temperature of sublimation system 112 below about 1900° C. and/or raising the pressure of the environment surrounding reaction crucible 114 above about 400 Torr.

Wafers cut from such SiC crystals may be subsequently used in the fabrication of various substrates. For example, using known techniques, high quality semiconductor wafers may be fabricated that include homo-epitaxial layers, such as SiC, as well as hetero-epitaxial layers, such as Group III-nitrides, on at least one surface thereof. The Group III-nitride layer may be, for example, GaN, AlGaN, AlN, AlInGaN, InN, and/or AlInN.

The SiC substrate will include at least one and possibly two primary (and opposing) surfaces. A plurality of active and/or passive devices may be fabricated on the SiC substrate.

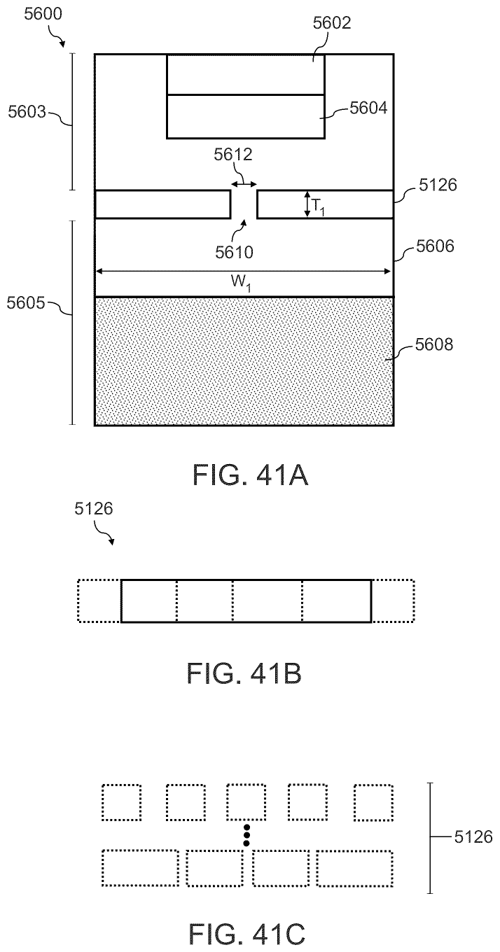

FIGS. 41A-48 depict example crystal growth systems that include a baffle according to example embodiments of the present disclosure. Any of the source material of the crystal growth systems of FIGS. 41A-48 may include a source material according to example embodiments of the present disclosure.

FIG. 41A depicts a simplified view of a crystal growth system 5600 according to example aspects of the present disclosure. The crystal growth system 5600 includes the seed holder 5602 configured to hold the seed crystal 5604. The seed crystal 5604 may provide a growth surface for growth of the silicon carbide crystalline material in a crystal growth process. The crystal growth system 5600 includes the crucible 5606 defining a crystal growth chamber. The crystal growth system 5600 includes the source material 5608. The crystal growth system 5600 includes a baffle 5126 within the crystal growth chamber that is spaced apart from the source material 5608. In some embodiments, the baffle 5126 may extend between the inner walls of the crucible 5606, such that the crucible 5606 is bisected or divided into an upper portion 5603 and a lower portion 5605 by the baffle 5126. The upper portion 5603 and the lower portion 5605 may have the same or different volumes. In some examples, the baffle 5126 may be coupled to a side wall of the crucible 5606. In some examples, the baffle 5126 may not fully extend between the inner walls of the crucible 5606.

The baffle 5126 has a long dimension (e.g., width) W1 and a thickness T1. The thickness T1 is in a general direction of vapor transport through the baffle 5126. In some embodiments, the long dimension W1 is in a direction that is non-perpendicular to the growth surface of the seed crystal 5604.

FIG. 41B depicts a simplified view of baffle 5126 according to some aspects of the present disclosure. As shown in FIG. 41B, baffle 5126 may include apertures, and may extend to the side walls of the crucible, or may not extend to the sidewalls of the crucible.

FIG. 41C depicts a simplified view of baffle 5126 according to some aspects of the present disclosure. As shown in FIG. 41C, baffle 5126 may include multiple baffle structures, which may be spaced apart from one another or may be in contact with one another.

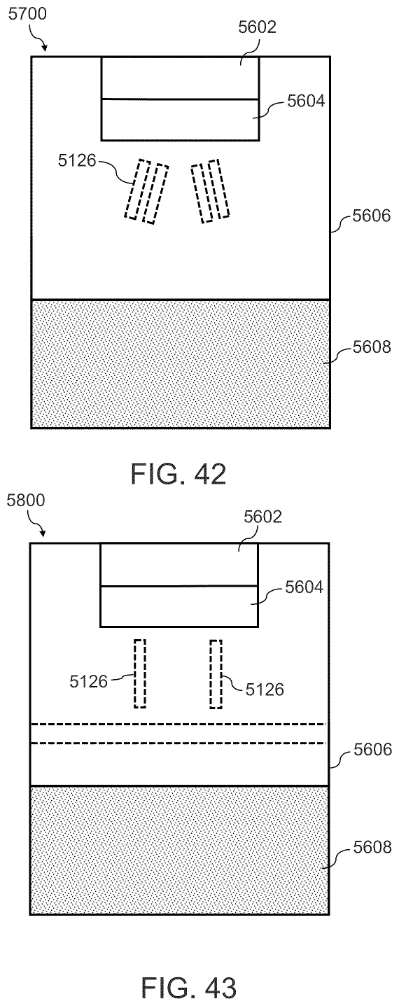

FIGS. 42, 43, 44, 45, 46, 47, and 48 depict simplified views of a baffle 5126 according to some aspects of the present disclosure in the context of crystal growth systems 5700, 5800, 5900, 6000, 6050, 6100, and 6200. As shown in FIG. 42, in some embodiments of the present disclosure, baffle 5126 may include one or more baffle plates, in any orientation relative to the seed holder 5602 or the source material 5608. As shown in FIG. 43, in some embodiments of the present disclosure, the baffle 5126 may include two or more baffle structures, whether of the same type or of differing types, and such baffle structures may be of differing orientations relative to each other.

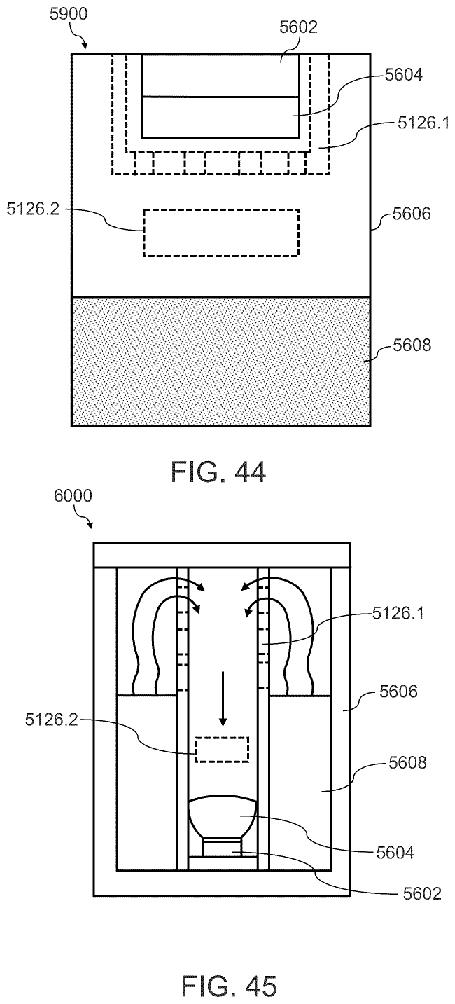

FIG. 44 depicts an example crystal growth system 5900 according to example embodiments of the present disclosure. In FIG. 44, the crystal growth system 5900 includes the baffle 5126.1, the seed holder 5602, the seed crystal 5604, the crucible 5606, and the source material 5608. The baffle 5126.1 may or may not include any apertures. The baffle 5126.1 may be porous graphite and may have a porosity of greater than about 70%. The baffle 5126 may be positioned such that the baffle 5126.1 extends around at least three sides of the seed crystal 5604, with the longest dimension located below the seed crystal 5604. The baffle 5126.1 may be referred to as a shell structure as it provides a shell around the seed crystal 5604. The baffle 5126 may be graphite, such as porous graphite. The baffle 5126.1 may include one or more apertures 5610 that assist in the transport of source vapor from the source material 5608 to the seed crystal 5604. The system 5900 may further include one or more second baffles 5126.2. The one or more second baffles 5126.2 may be arranged in the vapor transport path between the source material 5608 and the seed crystal 5604. The one or more second baffles 5126.2 may include any of the baffles disclosed in U.S. patent application Ser. No. 18/962,454 filed on Nov. 27, 2024, which is incorporated herein by reference.

FIG. 45 depicts an example crystal growth system 6000 according to example embodiments of the present disclosure. In FIG. 45, the crystal growth system 6000 includes a baffle 5126.1, a seed holder 5602, a seed crystal 5604, a crucible 5606, and the source material 5608. The baffle 5126.1 may include a tubular baffle structure. The baffle 5126.1 may or may not include apertures. The seed crystal 5604 may be within the tubular baffle 5126.1. The baffle 5126.1 may be graphite, such as porous graphite. The baffle 5126.1 may be porous graphite and may have a porosity of greater than about 70%. The baffle 5126.1 may include one or more apertures 5610 that assist in the transport of source vapor from the source material 5608 to the seed crystal 5604. The system 6000 may further include one or more second baffles 5126.2. The one or more second baffles 126.2 may be arranged in the vapor transport path between the source material 5608 and the seed crystal 5604. The one or more second baffles 5126.2 may include any of the baffles disclosed in U.S. patent application Ser. No. 18/962,454 filed on Nov. 27, 2024, which is incorporated herein by reference. The baffle 5126.1 and/or the baffle 5126.2 may serve to reduce graphite inclusions or other impurities resulting from gravitational forces pulling impurities toward the seed crystal 5604.

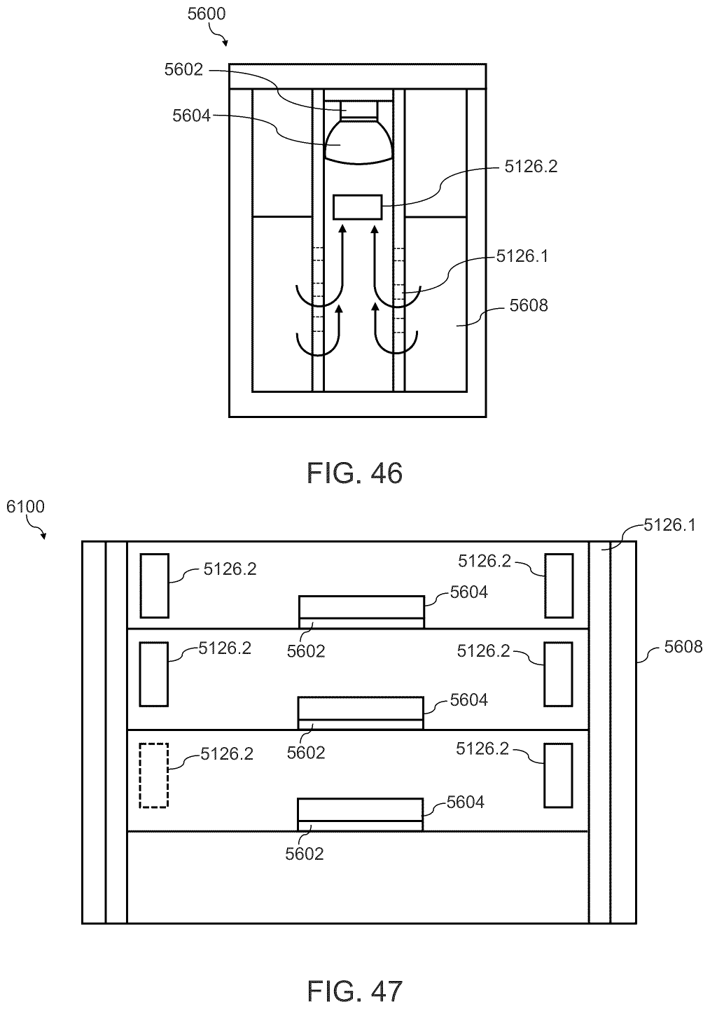

In FIG. 46, the crystal growth system 6050 includes the seed crystal 5604 at the top of the crucible 5606. Similar to FIG. 45, the baffle 5126.1 may include a tubular baffle structure. The seed crystal 5604 may be within the tubular baffle 5126.1. The baffle 5126.1 may be graphite, such as porous graphite. The baffle 5126.1 may be porous graphite and may have a porosity of greater than about 70%. The baffle 5126.1 may include one or more apertures 5610 that assist in the transport of source vapor from the source material 5608 to the seed crystal 5604. The system 6000 may further include one or more second baffles 5126.2. The one or more second baffles 5126.2 may be arranged in the vapor transport path between the source material 5608 and the seed crystal 5604. The one or more second baffles 5126.2 may include any of the baffles disclosed in U.S. patent application Ser. No. 18/962,454 filed on Nov. 27, 2024, which is incorporated herein by reference.

FIG. 47 depicts an example crystal growth system 6100 that may be used to grow a plurality of silicon carbide boules according to example embodiments of the present disclosure. In FIG. 47, the crystal growth system 6100 includes a plurality of seed holders 5602 and seed crystals 5604 arranged in different crystal growth chambers. A baffle 5126.1 may separate the seed crystals 5604 from a source material 5608. The baffle 5126.1 may include one or more apertures to assist with vapor transport from the source material 5608 to the seed crystals 5604. The system 6100 may further include one or more second baffles 5126.2. The one or more second baffles 5126.2 may be arranged in the vapor transport path between the source material 5608 and the seed crystal 5604. The one or more second baffles 5126.2 may include any of the baffles disclosed in U.S. patent application Ser. No. 18/962,454 filed on Nov. 27, 2024, which is incorporated herein by reference.

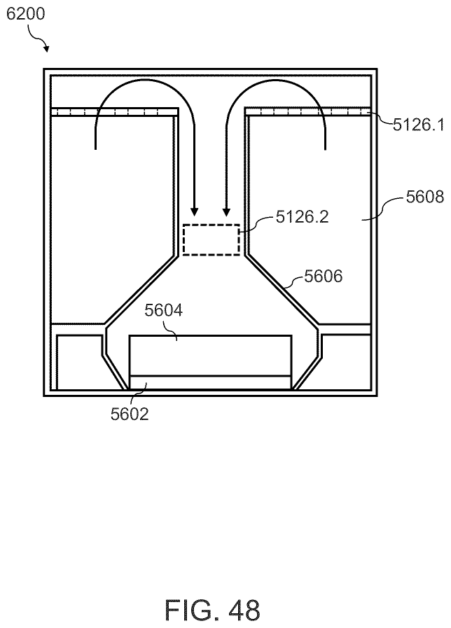

FIG. 48 depicts an example crystal growth system 6200 according to example embodiments of the present disclosure. In FIG. 48, the crystal growth system 6200 includes a seed holder 5602 and a seed crystal 5604 arranged within a crucible 5606. The crucible 5606 may have one or more angled sidewalls. The crystal growth system 6200 includes a source material 5608. The baffle 5126.1 may be on top of the source material 5608 and may separate the source material 5608 from the reaction chamber defined by the crucible 5606. As depicted in FIG. 23, the baffle 5126.1 may include one or more apertures to assist with vapor transport from the source material 5608 to the seed crystal 5604. The system 6100 may further include one or more second baffles 5126.2. The one or more second baffles 5126.2 may be arranged in the vapor transport path between the source material 5608 and the seed crystal 5604. The one or more second baffles 5126.2 may include any of the baffles disclosed in U.S. patent application Ser. No. 18/962,454 filed on Nov. 27, 2024, which is incorporated herein by reference.

In any of the simplified crystal growth systems with a baffle 5126.1, 5126.2 depicted in FIGS. 41A-48 or baffle 126 of FIGS. 1-3, the baffle may provide vapor transport of a silicon carbide source vapor through a first portion of the baffle at a first rate. In some embodiments, the silicon carbide vapor may be transported through a second portion of the baffle (e.g., including one or more apertures), at a second rate. The first rate may be different than the second rate. For example, the baffle may provide an avenue for source vapor to diffuse through the material of the baffle at a first rate, while source vapor is transported through an aperture unimpeded by the material of the baffle at a second rate.

In some embodiments, the baffle may be spaced apart from the seed holder and is not coupled to the seed holder. In some embodiments, the baffle may impede or otherwise alter heat transfer or thermal energy within the crystal growth chamber in a crystal growth process.

In some embodiments, the baffle may be, at least partially, made of graphite. In some embodiments, the baffle made at least partially of graphite may include a coating on at least a portion of the graphite. In some embodiments, the coating on the baffle made of graphite may be a pyrolytic coating. In some embodiments, the coating on the baffle made of graphite may be tantalum carbide. In some embodiments, the coating on the baffle may hinder particulate matter larger than the source vapor from reaching a seed crystal. The seed crystal may be a silicon carbide seed crystal. Example coatings that may be used are disclosed in U.S. Provisional Application Ser. No. 63/700,682, filed on Sep. 28, 2024, U.S. Provisional Application Ser. No. 63/700,685, filed on Sep. 28, 2024 and U.S. Provisional Application Ser. No. 63/700,686, filed on Sep. 28, 2024, which are incorporated herein by reference. The baffle may have undergone various treatments (e.g., may be a treated graphite structure) to reduce carbon inclusions in the baffle. Example treated graphite structures are disclosed in U.S. Provision Application Ser. No. 63/700,630, filed on Sep. 28, 2024 which is incorporated herein by reference.

In some examples, the graphite is porous graphite. For instance, the baffle may have a porosity in a range of about 50% to about 97%, such as about 75% to about 97%, such as about 80% to about 97%. Other suitable materials may be used without deviating from the scope of the present disclosure. For instance, the baffle may comprise a carbide material, such as vanadium carbide, tantalum carbide, silicon carbide. The carbide material may form a bulk of the baffle.

In some examples, at least a portion of the baffle includes uncoated graphite or exposed graphite. For instance, at least a portion of a surface of the baffle facing the seed crystal may be exposed or uncoated graphite. This will allow that baffle to serve as a secondary source to improve crystal growth during a PVT crystal growth process.

The seed crystal may be a silicon carbide seed crystal. In some embodiments, the baffle may be spaced apart from a seed holder and is not coupled to the seed holder. In some embodiments, the baffle may be spaced apart from a source material and is not coupled to the source material. The source material may be a silicon carbide vapor source material. In some embodiments, the baffle may be coupled to a side wall of a crucible. In some embodiments, the baffle, or an individual baffle plate in embodiments including a plurality of baffle plates or baffle structures, may have a thickness that is in a range of about 0.5 mm to about 25 mm, such as 2 mm to about 12 mm, such as about 2 mm to about 8 mm.

In some embodiments, the baffle can include single or multiple elements that perform one of more of the following: effecting/providing temperature gradient in a desired manner relative to the crystal growth surface, effecting/providing vapor pressure/flux/flow for/to/from the source material (e.g., silicon carbon source material, secondary source material, or dopant source relative to the crystal growth surface, side surface of the seed crystal and/or areas within the reactor susceptible to parasitic growth; and filtering graphite or other inclusions from the crystal. In some embodiments, different elements or portions of the baffle can provide different features, such as one element for filtering, another element acting as a secondary source (e.g., a graphite element that provides a carbon source and provides temperature gradient and vapor pressure/flux effects); and an element with apertures, pores, voids, cavities, indentations and/or protrusions to effect temperature gradient and/or vapor flow/pressure effects. One or more of the baffles 126 can be coated with a high temperature carbide, such as TaC or the like) while others are not. Portions or the entire baffle can be coated or not with a single, multiple and/or patterned coating(s), for instance, to achieve desired sublimation if acting as a secondary source, or to reduce sublimation if not intended to serve as a secondary source. Individual baffles or baffle elements can serve duplicate or different functions.

Example aspects of the present disclosure are set forth below. Any of the below features or examples may be used in combination with any of the embodiments or features provided in the present disclosure.

In an aspect, the present disclosure provides an example silicon carbide source material structure. In some implementations, the example silicon carbide source material structure includes a composite shaped solid.

In some implementations of the silicon carbide source material structure the composite shaped solid includes a hole.

In some implementations of the example silicon carbide source material structure, the composite shaped solid includes a void.

In some implementations of the example silicon carbide source material structure, the composite shaped solid includes a surface variation.

In some implementations of the example silicon carbide source material structure, the surface variation includes an inflection point.

In some implementations of the example silicon carbide source material structure, the surface variation includes a slot.

In some implementations of the example silicon carbide source material structure, the surface variation includes a projection.

In some implementations of the example silicon carbide source material structure, the projection includes a ridge.

In some implementations of the example silicon carbide source material structure, the projection includes a pedestal.

In some implementations of the example silicon carbide source material structure, the surface variation includes a peak.

In some implementations of the example silicon carbide source material structure, the surface variation includes a mound.

In some implementations of the example silicon carbide source material structure, the composite shaped solid includes a channel.

In some implementations of the example silicon carbide source material structure, the composite shaped solid includes an interconnection of substructures.

In some implementations of the example source material, the interconnected substructures are joined together at one or more joints.

In some implementations of the example silicon carbide source material structure, the composite shaped solid includes 2 or more joints.

In some implementations of the example silicon carbide source material structure, the substructures comprise one or more rods.

In some implementations of the example silicon carbide source material structure, the substructures comprise one or more facets.

In some implementations of the example silicon carbide source material structure, the one or more facets comprise one or more planar surfaces.

In some implementations of the example silicon carbide source material structure, the composite shaped solid includes at least two facets meeting at a seam, and wherein an angle defined by the two facets at the seam is from 10 to 80 degrees or from 100 to 170 degrees.

In some implementations of the example silicon carbide source material structure, the one or more facets comprise one or more curved surfaces.

In some implementations of the example silicon carbide source material structure, the substructures comprise one or more rectangular prisms.

In some implementations of the example silicon carbide source material structure, the substructures comprise one or more triangular prisms.

In some implementations of the example silicon carbide source material structure, the composite shaped solid includes a plurality of microparticles bound together.

In some implementations of the example silicon carbide source material structure, the composite shaped solid has a material density from about 1.4 g/cm3 to about 3.1 g/cm3.

In some implementations of the example silicon carbide source material structure, the composite shaped solid has a material density from about 2.0 g/cm3 to about 2.6 g/cm3.

In some implementations of the example silicon carbide source material structure, the composite shaped solid has a total porosity from about 50% to about 80%.

In some implementations of the example silicon carbide source material structure, the composite shaped solid has a ratio of open porosity to total porosity of from about 0.8 to about 1.

In some implementations of the example silicon carbide source material structure, the composite shaped solid has a ratio of source density to material density of 0.9 or less.

In some implementations of the example silicon carbide source material structure, the composite shaped solid includes silicon carbide.

In some implementations of the example silicon carbide source material structure, the composite shaped solid further includes graphite.

In some implementations of the example silicon carbide source material structure, the composite shaped solid further includes a dopant.

In some implementations of the example silicon carbide source material structure, the composite shaped solid has an average grain size from about 1 μm to about 200 μm.

In some implementations of the example silicon carbide source material structure, the composite shaped solid includes at least one 3D-printed structure.

In some implementations of the example silicon carbide source material structure, the composite shaped solid includes at least one extruded silicon carbide structure.

In some implementations of the example silicon carbide source material structure, the composite shaped solid includes at least one casted silicon carbide structure.

In some implementations of the example silicon carbide source material structure, the composite shaped solid includes at least one hot pressed silicon carbide structure.

In some implementations of the example silicon carbide source material structure, the composite shaped solid includes at least one sintered silicon carbide structure.

In some implementations of the example silicon carbide source material structure, the composite shaped solid includes at least one graphite converted solid silicon carbide structure.

In some implementations of the example silicon carbide source material structure, the graphite converted solid silicon carbide structure is converted from a graphite preform.

In some implementations of the example silicon carbide source material structure, the graphite preform includes a needle coke structure.

In some implementations of the example silicon carbide source material structure, the graphite preform has a density in a range of 1.4 to 1.6 g/cc.

In some implementations of the example silicon carbide source material structure, the graphite preform has a raito of open porosity to total porosity in a range of 0.9 to 1.

In some implementations of the example silicon carbide source material structure, the graphite preform has a grain size in a range of 1 micron to 20 microns.

In an aspect, the present disclosure provides a silicon carbide source material structure for use in a sublimation system for growing single crystal silicon carbide, the silicon carbide source material structure comprising: two or more shaped solids having a volume of 30 cm3 or greater.

In some implementations of the example silicon carbide source material structure, the shaped solids comprise one or more rods.

In some implementations of the example silicon carbide source material structure, the shaped solids comprise one or more tubes.

In some implementations of the example silicon carbide source material structure, the shaped solids comprise at least one rod and one tube.

In some implementations of the example silicon carbide source material structure, the shaped solids comprise a plurality of rods surrounding a tube.

In some implementations of the example silicon carbide source material structure, at least one of the shaped solids includes one or more composite shaped solids.

In some implementations of the example silicon carbide source material structure, at least one of the shaped solids has a material density from about 1.4 g/cm3 to about 3.1 g/cm3.

In some implementations of the example silicon carbide source material structure, at least one of the shaped solids has a material density from about 2.0 g/cm3 to about 2.6 g/cm3.

In some implementations of the example silicon carbide source material structure, at least one of the shaped solids has a total porosity from about 50% to about 80%.

In some implementations of the example silicon carbide source material structure, at least one of the shaped solids has a ratio of open porosity to total porosity of from about 0.8 to about 1.

In some implementations of the example silicon carbide source material structure, at least one of the shaped solids includes silicon carbide.

In some implementations of the example silicon carbide source material structure, the at least one shaped solid further includes graphite.

In some implementations of the example silicon carbide source material structure, the at least one shaped solid further includes a dopant.

In some implementations of the example silicon carbide source material structure, at least one of the shaped solids has an average grain size from about 1 μm to about 200 μm.

In some implementations of the example silicon carbide source material structure, at least one of the shaped solids includes at least one 3D-printed structure.

In some implementations of the example silicon carbide source material structure, at least one of the shaped solids includes at least one extruded silicon carbide structure.

In some implementations of the example silicon carbide source material structure, at least one of the shaped solids includes at least one casted silicon carbide structure.

In some implementations of the example silicon carbide source material structure, at least one of the shaped solids includes at least one hot pressed silicon carbide structure.

In some implementations of the example silicon carbide source material structure, at least one of the shaped solids includes at least one sintered silicon carbide structure.

In some implementations of the example silicon carbide source material structure, at least one of the shaped solids includes at least one graphite converted solid silicon carbide structure.

In some implementations of the example silicon carbide source material structure, the graphite converted solid silicon carbide structure is converted from a graphite preform.

In some implementations of the example silicon carbide source material structure, the graphite preform includes a needle coke structure.

In some implementations of the example silicon carbide source material structure, the graphite preform has a density in a range of 1.4 to 1.6 g/cc.

In some implementations of the example silicon carbide source material structure, the graphite preform has a ratio of open porosity to total porosity in a range of 0.9 to 1.

In some implementations of the example silicon carbide source material structure, the graphite preform has a grain size in a range of 1 micron to 20 microns.

In an aspect, the present disclosure provides a silicon carbide source material structure for use in a sublimation system for growing single crystal silicon carbide, the source material structure comprising: a shaped solid having a volume and a surface area, wherein the ratio of the surface area to the volume is about 2.0 cm⁻¹ or greater.

In some implementations of the example silicon carbide source material structure, the shaped solid has a length of at least 20 mm in a first direction and a length of at least 10 mm in a direction orthogonal to the first direction.

In some implementations of the example silicon carbide source material structure, the shaped solid has a material density from about 1.4 g/cm3 to about 3.1 g/cm3.

In some implementations of the example silicon carbide source material structure, the shaped solid has a material density from about 2.0 g/cm3 to about 2.6 g/cm3.

In some implementations of the example silicon carbide source material structure, the shaped solid has a total porosity from about 50% to about 80%.

In some implementations of the example silicon carbide source material structure, the shaped solid has a ratio of open porosity to total porosity of from about 0.8 to about 1.

In some implementations of the example silicon carbide source material structure, the composite shaped solid has a ratio of source density to material density of 0.9 or less.

In some implementations of the example silicon carbide source material structure, the shaped solid includes silicon carbide.

In some implementations of the example silicon carbide source material structure, the shaped solid further includes graphite.

In some implementations of the example silicon carbide source material structure, the shaped solid further includes a dopant.

In some implementations of the example silicon carbide source material structure, the shaped solid has an average grain size from about 1 μm to about 200 μm.

In some implementations of the example silicon carbide source material structure, the shaped solid includes at least one 3D-printed structure.

In some implementations of the example silicon carbide source material structure, the shaped solid includes at least one extruded silicon carbide structure.

In some implementations of the example silicon carbide source material structure, the shaped solid includes at least one casted silicon carbide structure.

In some implementations of the example silicon carbide source material structure, the shaped solid includes at least one hot pressed silicon carbide structure.

In some implementations of the example silicon carbide source material structure, the shaped solid includes at least one sintered silicon carbide structure.

In some implementations of the example silicon carbide source material structure, the shaped solid includes at least one graphite converted solid silicon carbide structure.

In some implementations of the example silicon carbide source material structure, the graphite converted solid silicon carbide structure is converted from a graphite preform.

In some implementations of the example silicon carbide source material structure, the graphite preform includes a needle coke structure.

In some implementations of the example silicon carbide source material structure, the graphite preform has a density in a range of 1.4 to 1.6 g/cc.

In some implementations of the example silicon carbide source material structure, the graphite preform has a ratio of open porosity to total porosity in a range of 0.9 to 1.

In some implementations of the example silicon carbide source material structure, the graphite preform has a grain size in a range of 1 micron to 20 microns.

In an aspect, the present disclosure provides an example source material for use in a sublimation system for growing single crystal silicon carbide, the source material structure comprising: a shaped solid comprising at least one internal void having a volume of 1 mm³ or greater.

In some implementations of the example silicon carbide source material structure, the shaped solid includes 2 or more internal voids having a volume of 1 mm3 or greater.

In some implementations of the example silicon carbide source material structure, the shaped solid has a material density from about 1.4 g/cm3 to about 3.1 g/cm3.

In some implementations of the example silicon carbide source material structure, the shaped solid has a material density from about 2.0 g/cm3 to about 2.6 g/cm3.

In some implementations of the example silicon carbide source material structure, the shaped solid has a total porosity from about 50% to about 80%.

In some implementations of the example silicon carbide source material structure, the shaped solid has a ratio of open porosity to total porosity of from about 0.8 to about 1.

In some implementations of the example silicon carbide source material structure, the composite shaped solid has a ratio of source density to material density of 0.9 or less.

In some implementations of the example silicon carbide source material structure, the shaped solid includes silicon carbide.

In some implementations of the example silicon carbide source material structure, the shaped solid further includes graphite.

In some implementations of the example silicon carbide source material structure, the shaped solid further includes a dopant.

In some implementations of the example silicon carbide source material structure, the shaped solid has an average grain size from about 1 μm to about 200 μm.

In some implementations of the example silicon carbide source material structure, the shaped solid includes at least one 3D-printed structure.

In some implementations of the example silicon carbide source material structure, the shaped solid includes at least one extruded silicon carbide structure.

In some implementations of the example silicon carbide source material structure, the shaped solid includes at least one casted silicon carbide structure.

In some implementations of the example silicon carbide source material structure, the shaped solid includes at least one hot pressed silicon carbide structure.

In some implementations of the example silicon carbide source material structure, the shaped solid includes at least one sintered silicon carbide structure.

In some implementations of the example silicon carbide source material structure, the shaped solid includes at least one graphite converted solid silicon carbide structure.

In some implementations of the example silicon carbide source material structure, the graphite converted solid silicon carbide structure is converted from a graphite preform.

In some implementations of the example silicon carbide source material structure, the graphite preform includes a needle coke structure.

In some implementations of the example silicon carbide source material structure, the graphite preform has a density in a range of 1.4 to 1.6 g/cc.

In some implementations of the example silicon carbide source material structure, the graphite preform has a ratio of open porosity to total porosity in a range of 0.9 to 1.

In some implementations of the example silicon carbide source material structure, the graphite preform has a grain size in a range of 1 micron to 20 microns.

In an aspect, the present disclosure provides a silicon carbide source material structure for use in a sublimation system for growing single crystal silicon carbide, the source material structure comprising: a shaped solid structure having a surface and a hole extending from the surface into an interior of the solid structure, the hole having a depth of at least 1 mm from the surface.

In some implementations of the example silicon carbide source material structure, the surface is a curved surface and the depth is the distance from a perimeter of the hole to the maximum depth of the hole in a direction normal to the surface at the perimeter.

In some implementations of the example silicon carbide source material structure, the hole includes a channel running from one surface of the shaped solid structure to a second surface of the shaped solid structure.

In some implementations of the example silicon carbide source material structure, the hole extends only partially through the shaped solid structure such that it does not reach a second surface.

In some implementations of the example silicon carbide source material structure, the hole has a curved perimeter.

In some implementations of the example silicon carbide source material structure, the hole has a rectangular perimeter.

In some implementations of the example silicon carbide source material structure, the shaped solid structure has 2 or more holes.

In some implementations of the example silicon carbide source material structure, the shaped solid has a material density from about 1.4 g/cm3 to about 3.1 g/cm3.

In some implementations of the example silicon carbide source material structure, the shaped solid has a material density from about 2.0 g/cm3 to about 2.6 g/cm3.

In some implementations of the example silicon carbide source material structure, the shaped solid has a total porosity from about 50% to about 80%.

In some implementations of the example silicon carbide source material structure, the shaped solid has a ratio of open porosity to total porosity of from about 0.8 to about 1.

In some implementations of the example silicon carbide source material structure, the composite shaped solid has a ratio of source density to material density of 0.9 or less.

In some implementations of the example silicon carbide source material structure, the shaped solid includes silicon carbide.

In some implementations of the example silicon carbide source material structure, the shaped solid further includes graphite.

In some implementations of the example silicon carbide source material structure, the shaped solid further includes a dopant.

In some implementations of the example silicon carbide source material structure, the shaped solid has an average grain size from about 1 μm to about 200 μm.

In some implementations of the example silicon carbide source material structure, the shaped solid includes at least one 3D-printed structure.

In some implementations of the example silicon carbide source material structure, the shaped solid includes at least one extruded silicon carbide structure.

In some implementations of the example silicon carbide source material structure, the shaped solid includes at least one casted silicon carbide structure.

In some implementations of the example silicon carbide source material structure, the shaped solid includes at least one hot pressed silicon carbide structure.

In some implementations of the example silicon carbide source material structure, the shaped solid includes at least one sintered silicon carbide structure.

In some implementations of the example silicon carbide source material structure, the shaped solid includes at least one graphite converted solid silicon carbide structure.

In some implementations of the example silicon carbide source material structure, the graphite converted solid silicon carbide structure is converted from a graphite preform.

In some implementations of the example silicon carbide source material structure, the graphite preform includes a needle coke structure.

In some implementations of the example silicon carbide source material structure, the graphite preform has a density in a range of 1.4 to 1.6 g/cc.

In some implementations of the example silicon carbide source material structure, the graphite preform has a ratio of open porosity to total porosity in a range of 0.9 to 1.

In some implementations of the example silicon carbide source material structure, the graphite preform has a grain size in a range of 1 micron to 20 microns.

In an aspect, the present disclosure is directed to a silicon carbide source material structure for use in a sublimation system for growing single crystal silicon carbide, the source material structure comprising: a shaped solid structure having a volume, wherein a ratio of the volume to the volume of the smallest right cylinder that would fully contain the shaped solid structure is about 0.9 or less.

In some implementations of the example silicon carbide source material structure, the shaped solid has a material density from about 1.4 g/cm3 to about 3.1 g/cm3.

In some implementations of the example silicon carbide source material structure, the shaped solid has a material density from about 2.0 g/cm3 to about 2.6 g/cm3.

In some implementations of the example silicon carbide source material structure, the shaped solid has a total porosity from about 50% to about 80%.

In some implementations of the example silicon carbide source material structure, the shaped solid has a ratio of open porosity to total porosity of from about 0.8 to about 1.

In some implementations of the example silicon carbide source material structure, the shaped solid includes silicon carbide.

In some implementations of the example silicon carbide source material structure, the shaped solid further includes graphite.

In some implementations of the example silicon carbide source material structure, the shaped solid further includes a dopant.

In some implementations of the example silicon carbide source material structure, the shaped solid has an average grain size from about 1 μm to about 200 μm.

In some implementations of the example silicon carbide source material structure, the shaped solid includes at least one 3D-printed structure.

In some implementations of the example silicon carbide source material structure, the shaped solid includes at least one extruded silicon carbide structure.

In some implementations of the example silicon carbide source material structure, the shaped solid includes at least one casted silicon carbide structure.

In some implementations of the example silicon carbide source material structure, the shaped solid includes at least one hot pressed silicon carbide structure.

In some implementations of the example silicon carbide source material structure, the shaped solid includes at least one sintered silicon carbide structure.

In some implementations of the example silicon carbide source material structure, the shaped solid includes at least one graphite converted solid silicon carbide structure.

In some implementations of the example silicon carbide source material structure, the graphite converted solid silicon carbide structure is converted from a graphite preform.

In some implementations of the example silicon carbide source material structure, the graphite preform includes a needle coke structure.

In some implementations of the example silicon carbide source material structure, the graphite preform has a density in a range of 1.4 to 1.6 g/cc.

In some implementations of the example silicon carbide source material structure, the graphite preform has a ratio of open porosity to total porosity in a range of 0.9 to 1.

In some implementations of the example silicon carbide source material structure, the graphite preform has a grain size in a range of 1 micron to 20 microns.

In an aspect, the present disclosure is directed to a silicon carbide source material structure for use in a sublimation system for growing single crystal silicon carbide, the source material structure comprising: a composite shaped solid comprising a first portion configured to provide a first sublimation rate during a crystal growth process and a second portion configured to provide a second sublimation rate during a crystal growth process, wherein the second sublimation rate is different from the first sublimation rate.

In some implementations of the example silicon carbide source material structure, the composite shaped solid includes a first shaped solid and a second shaped solid, the second shaped solid having a different size or shape from the first shaped solid.

In some implementations of the example silicon carbide source material structure, the first shaped solid is a sphere having a first size and the second shaped solid is a sphere having a second size different from the first size.

In some implementations of the example silicon carbide source material structure, the first shaped solid is a rod having a first diameter and the second shaped solid is a rod having a second size different from the first size.

In some implementations of the example silicon carbide source material structure, the composite shaped solid includes a first substructure and a second substructure, the second substructure having a different size or shape from the first substructure.

In some implementations of the example silicon carbide source material structure, the first portion is in a central portion of the source material structure and the second portion is in a peripheral portion of the source material structure.

In some implementations of the example silicon carbide source material structure, the first portion is in a lower portion of the source material structure and the second portion is in an upper portion of the source material structure.

In some implementations of the example silicon carbide source material structure, the composite shaped solid includes a first void and a second void, the second void having a different size from the first void.

In some implementations of the example silicon carbide source material structure, the second portion has a higher ratio of surface area to volume of silicon carbide than the first area.

In an aspect, the present disclosure provides an example silicon carbide crystal growth sublimation system including a crucible and a silicon carbide source material according to any of the preceding paragraphs. In some examples the silicon carbide crystal growth sublimation system includes a seed material.

In some examples, the present disclosure provides an example method. The method includes placing the silicon carbide source material structure according to any preceding claim in a reaction crucible; and heating the sublimation system to at least a sublimation temperature of the silicon carbide source material structure.

While the present subject matter has been described in detail with respect to specific example embodiments thereof, it will be appreciated that those skilled in the art, upon attaining an understanding of the foregoing can readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

What is claimed is:

1. A silicon carbide source material structure for use in a sublimation system for growing single crystal silicon carbide, the silicon carbide source material structure comprising:
a composite shaped solid.

2. The silicon carbide source material structure of claim 1, wherein the composite shaped solid comprises a hole.

3. The silicon carbide source material structure of claim 1, wherein the composite shaped solid comprises a void.

4. The silicon carbide source material structure of claim 1, wherein the composite shaped solid comprises a surface variation.

5. The silicon carbide source material structure of claim 4, wherein the surface variation comprises an inflection point.

6. The silicon carbide source material structure of claim 4, wherein the surface variation comprises a slot.

7. The silicon carbide source material structure of claim 4, wherein the surface variation comprises a projection.

8. The silicon carbide source material structure of claim 4, wherein the projection comprises a ridge.

9. The silicon carbide source material structure of claim 8, wherein the projection comprises a pedestal.

10. The silicon carbide source material structure of claim 8, wherein the surface variation comprises a peak.

11. The silicon carbide source material structure of claim 8, wherein the surface variation comprises a mound.

12. The silicon carbide source material structure of claim 1, wherein the composite shaped solid comprises a channel.

13. The silicon carbide source material structure of claim 1, wherein the composite shaped solid comprises an interconnection of substructures.

14. The source material of claim 13, wherein the interconnected substructures are joined together at one or more joints.

15. The silicon carbide source material structure of claim 13, wherein the substructures comprise one or more rods.

16. The silicon carbide source material structure of claim 13, wherein the substructures comprise one or more facets.

17. The silicon carbide source material structure of claim 16, wherein the one or more facets comprise one or more curved surfaces.

18. The silicon carbide source material structure of claim 1, wherein the composite shaped solid has a material density from about 1.4 g/cm³ to about 3.1 g/cm³.

19. The silicon carbide source material structure of claim 1, wherein the composite shaped solid has a total porosity from about 50% to about 80%.

20. The silicon carbide source material structure of claim 1, wherein the composite shaped solid comprises silicon carbide.
